(19) United States
(12) Patent Application Publication
(10) Pub. No.: US 2024/0312877 A1
(43) Pub. Date: Sep. 19, 2024

(54) SEMICONDUCTOR DEVICE

(71) Applicant: Rohm Co., Ltd., Kyoto-shi (JP)

(72) Inventors: Yoshizo OSUMI, Kyoto-shi (JP); Keiji WADA, Kyoto-shi (JP)

(21) Appl. No.: 18/670,165

(22) Filed: May 21, 2024

Related U.S. Application Data
(63) Continuation of application No. PCT/JP2022/042243, filed on Nov. 14, 2022.

(30) Foreign Application Priority Data
Nov. 29, 2021 (JP) 2021-192779

(51) Int. Cl. H01L 23/495; H01L 23/00; H01L 23/31

(52) U.S. Cl. CPC H01L 23/49506; H01L 23/3107; H01L 23/49575; H01L 24/48; H01L 2224/48137; H01L 2224/48245; H01L 2924/1206; H01L 2924/1426

(57) ABSTRACT

A semiconductor device includes a die pad, a first semiconductor element and a second semiconductor element each mounted on the die pad, and an insulating element electrically connected to the first semiconductor element and the second semiconductor element and insulating the first semiconductor element and the second semiconductor element from each other. The semiconductor device further includes a dummy element bonded to the die pad and a first bonding layer bonding the dummy element and the insulating element. The dummy element includes an insulating layer located between the die pad and the first bonding layer in a thickness direction.

### TECHNICAL FIELD

The present disclosure relates to a semiconductor device.

### BACKGROUND ART

Inverter devices used in electric vehicles, home appliances, etc., have a plurality of semiconductor elements mounted therein. Such semiconductor elements include a plurality of switching elements (e.g., IGBTs), a drive element (gate driver) that drives the switching elements, and a control element (controller) that controls the drive element. In the inverter device, an electric signal produced by a different inverter device is inputted to the control element. The control element converts the electric signal to a PWM (Pulse Width Modulation) control signal and transmits it to the drive element. Based on the PWM control signal, the drive element drives six switching elements, for example, at appropriate timings. In this way, DC power is converted into three-phase AC power for motor driving. An example of a semiconductor device that forms a part of an inverter device is disclosed in JP-A-2016-207714.

The semiconductor device disclosed in JP-A-2016-207714 has a control element and a drive element mounted therein. Because the power supply voltage supplied to the drive element is not less than the voltage applied to the switching elements, the power supply voltage supplied to the control element and the power supply voltage supplied to the drive element differ from each other. This results in a difference between the voltage applied to the control element and its conduction path and the voltage applied to the drive element and its conduction path. In the semiconductor device disclosed in JP-A-2016-207714, the control element and its conductive path and the drive element and its conductive path are insulated from each other by interposing an insulating element in the path for electric signal transmission between the control element and the drive element. In this way, dielectric breakdown of the control element and the drive element is prevented. The insulating element is mounted on a die pad on which either the control element or the drive element is mounted. Therefore, when the difference between the voltage applied to the conduction path of the control element and the voltage applied to the conduction path of the drive element is considerably large, the risk of dielectric breakdown of the insulating element increases.

### BRIEF DESCRIPTION OF THE DRAWINGS

FIG. 1 is a plan view of a semiconductor device according to a first embodiment of the present disclosure.

FIG. 2 is a plan view corresponding to FIG. 1, with a sealing resin shown only in its outlines.

FIG. 3 is a front view of the semiconductor device shown in FIG. 1.

FIG. 4 is a left side view of the semiconductor device shown in FIG. 1.

FIG. 5 is a right side view of the semiconductor device shown in FIG. 1.

FIG. 6 is a sectional view taken along line VI-VI in FIG. 2.

FIG. 7 is a sectional view taken along line VII-VII in FIG. 2.

FIG. 8 is a partially enlarged view in which a portion of FIG. 2 is enlarged.

FIG. 9 is a sectional view taken along line IX-IX in FIG. 8.

FIG. 10 is a schematic view of the insulating element and the dummy element shown in FIG. 9.

FIG. 11 is a partially enlarged sectional view of a semiconductor device according to a first variation of the first embodiment of the present disclosure.

FIG. 12 is a partially enlarged sectional view of a semiconductor device according to a second variation of the first embodiment of the present disclosure.

FIG. 13 is a partially enlarged sectional view of a semiconductor device according to a third variation of the first embodiment of the present disclosure.

FIG. 14 is a partially enlarged plan view of a semiconductor device according to a second embodiment of the present disclosure, in which illustration of the sealing resin is omitted.

FIG. 15 is a bottom view of the dummy element of the semiconductor device shown in FIG. 14.

FIG. 16 is a sectional view taken along line XVI-XVI in FIG. 14.

FIG. 17 is a partially enlarged plan view of a semiconductor device according to a third embodiment of the present disclosure, in which illustration of the sealing resin is omitted.

FIG. 18 is a sectional view taken along line XVIII-XVIII in FIG. 17.

FIG. 19 is a plan view of a semiconductor device according to a fourth embodiment of the present disclosure, with the sealing resin shown only in its outlines.

FIG. 20 is a sectional view taken along line XX-XX in FIG. 19.

FIG. 21 is a plan view of a semiconductor device according to a fifth embodiment of the present disclosure, with the sealing resin shown only in its outlines.

FIG. 22 is a sectional view taken along line XXII-XXII in FIG. 21.

FIG. 23 is a partially enlarged view in which a portion of FIG. 21 is enlarged.

FIG. 24 is a sectional view taken along line XXIV-XXIV in FIG. 23.

FIG. 25 is a schematic view of the insulating element and the dummy element shown in FIG. 24.

FIG. 26 is a plan view of a semiconductor device according to a sixth embodiment of the present disclosure, with the sealing resin shown only in its outlines.

FIG. 27 is a sectional view taken along line XXVII-XXVII in FIG. 26.

FIG. 28 is a partially enlarged view in which a portion of FIG. 27 is enlarged.

### DETAILED DESCRIPTION OF EMBODIMENTS

The following describes modes for carrying out the present disclosure with reference to the drawings.

### First Embodiment

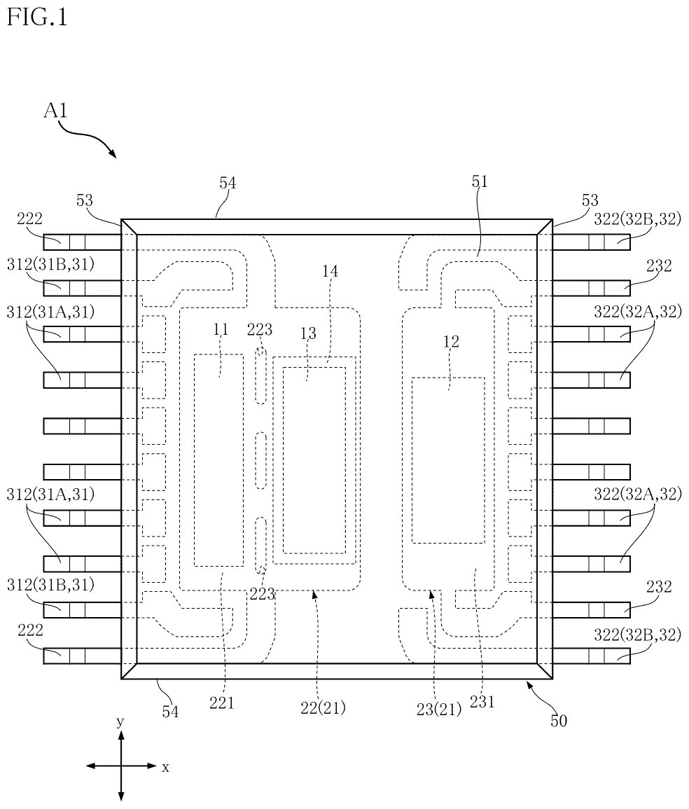

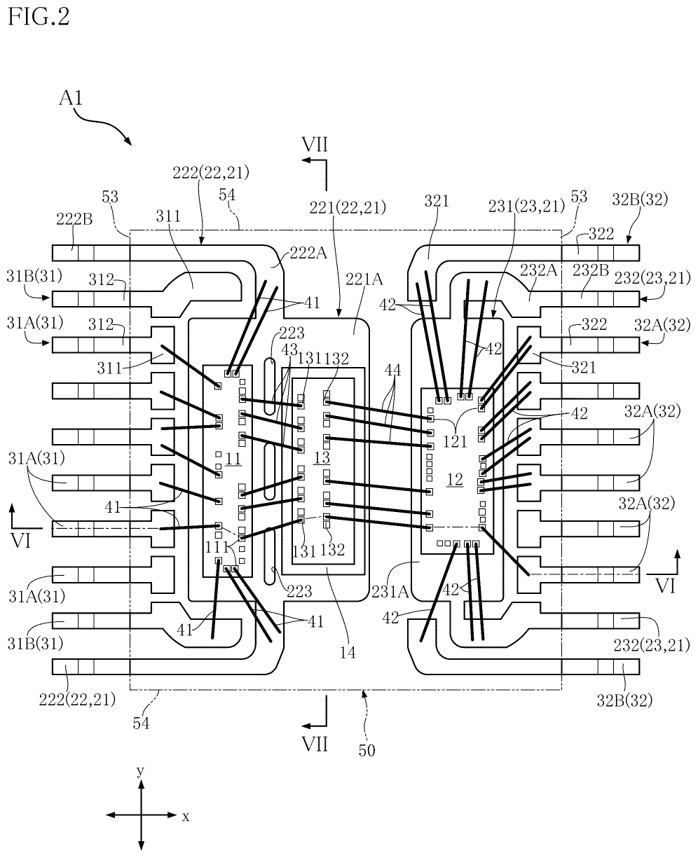

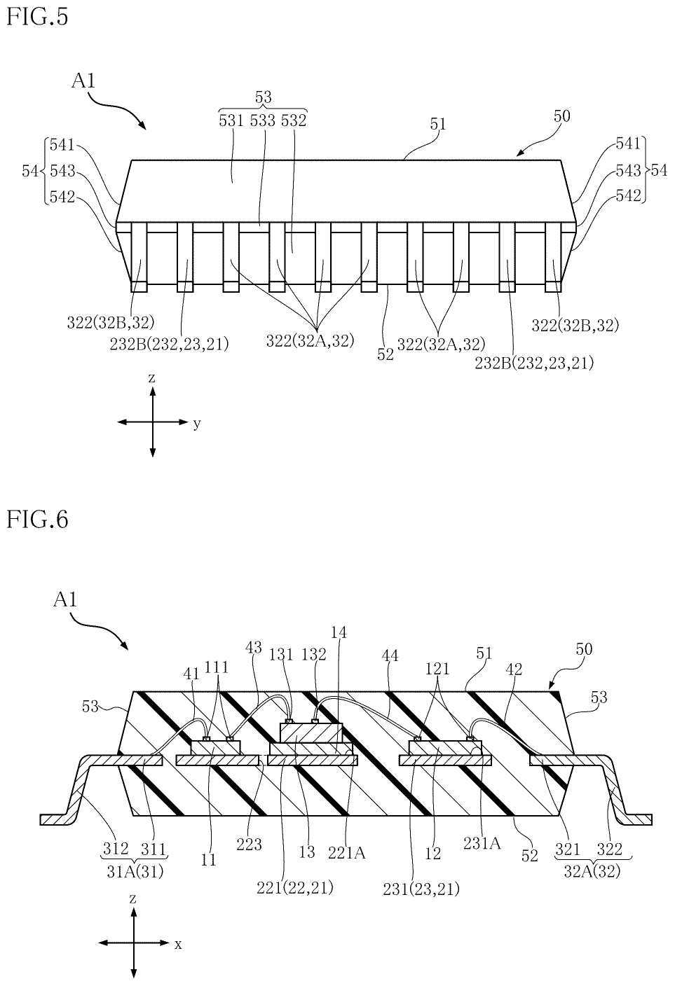

A semiconductor device A1 according to a first embodiment of the present disclosure will be described based in FIGS. 1 to 10. The semiconductor device A1 includes a first semiconductor element 11, a second semiconductor element 12, an insulating element 13, a die pad 21, a plurality of first terminals 31, a plurality of second terminals 32, a dummy element 14, a first bonding layer 18, a second bonding layer 19, and a sealing resin 50. The semiconductor device A1 further includes a plurality of first wires 41, a plurality of second wires 42, a plurality of third wires 43, and a plurality of fourth wires 44. The semiconductor device A1 is configured to be surface-mounted on a wiring board of an inverter device for an electric vehicle or a hybrid vehicle, for example. The package type of the semiconductor device A1 is the SOP (Small Outline Package). The package type of the semiconductor device A1 is not limited to the SOP. FIG. 2 illustrates the sealing resin 50 only in its outlines for convenience of understanding. In FIG. 2, the outlines of the sealing resin 50 are shown by imaginary lines (dash-double dot lines).

In the description of the semiconductor device A1, the thickness direction of the first semiconductor element 11 is referred to as the “thickness direction z”. The thickness direction z corresponds to the direction which is normal to the first mounting surface 221A of the first pad portion (first die pad 22), described later. A direction orthogonal to the thickness direction z is referred to as the “first direction x”. The direction orthogonal to the thickness direction z and the first direction x is referred to as the “second direction y”.

The first semiconductor element 11, the second semiconductor element 12, and the insulating element 13 are the core components for the functions of the semiconductor device A1. In the semiconductor device A1, the first semiconductor element 11, the second semiconductor element 12, and the insulating element 13 are individual elements. The second semiconductor element 12 is located opposite to the first semiconductor element 11 with respect to the insulating element 13 in the first direction x. As viewed in the thickness direction z, each of the first semiconductor element 11, the second semiconductor element 12 and the insulating element 13 has a rectangular shape that is relatively long along the second direction y.

The first semiconductor element 11 is a controller (a control element) that controls a gate driver, described later. The first semiconductor element 11 is provided with a circuit that converts electric signals inputted from other semiconductor devices PWM control signals, a into transmission circuit that transmits the PWM control signals to the second semiconductor element 12, and a reception circuit that receives electric signals from the second semiconductor element 12.

The second semiconductor element 12 is a gate driver (drive element) for driving a switching element. The switching element is, for example, an IGBT (Insulated Gate Bipolar Transistor) or a MOSFET (Metal-Oxide-Semiconductor Field-Effect Transistor). The second semiconductor element 12 is provided with a receiving circuit for receiving PWM control signals, a circuit for driving the switching elements based on the PWM control signals, and a transmission circuit for transmitting electric signals to the first semiconductor element 11. Examples of the electric signals include output signals from a temperature sensor disposed near a motor.

The insulating element 13 is an element that transmits PWM control signals and other electric signals in an insulated condition. In the semiconductor device A1, the insulating element 13 is of an inductive type. An example of the inductive type insulating element 13 is an insulation transformer. An insulation transformer includes two inductively coupled inductors (coils) to realize transmission of electric signals in an insulated state. The insulating element 13 has a substrate made of silicon. Inductors made of copper (Cu) are formed on the substrate. The inductors include a transmitting-side inductor and a receiving-side inductor, which are stacked in the thickness direction z. A dielectric layer made of silicon dioxide (SiO₂), for example, is interposed between the transmitting-side inductor and the receiving-side inductor. The dielectric layer provides electrical insulation between the transmitting-side inductor and the receiving-side inductor. Alternatively, the insulating element 13 may be of a capacitive type. An example of the capacitive insulating element 13 is a capacitor.

The voltage applied to the first semiconductor element 11 and the voltage applied to the second semiconductor element 12 differ from each other. Thus, there is a potential difference between the first semiconductor element 11 and the second semiconductor element 12. In the semiconductor device A1, the voltage applied to the second semiconductor element 12 is higher than the voltage applied to the first semiconductor element 11. In addition, in the semiconductor device A1, the power supply voltage supplied to the second semiconductor element 12 is higher than the power supply voltage supplied to the first semiconductor element 11.

In the semiconductor device A1, therefore, the insulating element 13 provides insulation between a first circuit including the first semiconductor element 11 as a component the second semiconductor and a second circuit including element 12 as a component. The insulating element 13 is electrically connected to the first circuit and the second circuit. The components of the first circuit include a first die pad 22 described later, the first terminals 31, the first wires 41 and the third wires 43, in addition to the first semiconductor element 11. The components of the second circuit include a second die pad 23 described later, the second terminals 32, the second wires 42 and the fourth wires 44, in addition to the second semiconductor element 12. The first circuit and the second circuit have different potentials. In the semiconductor device A1, the potential of the second circuit is higher than the potential of the first circuit. In this state, the insulating element 13 relays signals between the first circuit and the second circuit. For example, in an inverter device for an electric vehicle or a hybrid vehicle, the voltage applied to the ground of the second semiconductor element 12 may transiently become 600 V or higher while the voltage applied to the ground of the first semiconductor element 11 is about 0 V.

As shown in FIGS. 2 and 6, the first semiconductor element 11 has a plurality of first electrodes 111. The first electrodes 111 are on the upper surface of the first semiconductor element 11 (the surface facing in the same direction as a first mounting surface 221A of a first pad portion 221 of the first die pad 22, described later). The composition of the first electrodes 111 includes aluminum (Al), for example. In other words, each first electrode 111 contains aluminum. The first electrodes 111 are electrically connected to the circuit formed in the first semiconductor element 11.

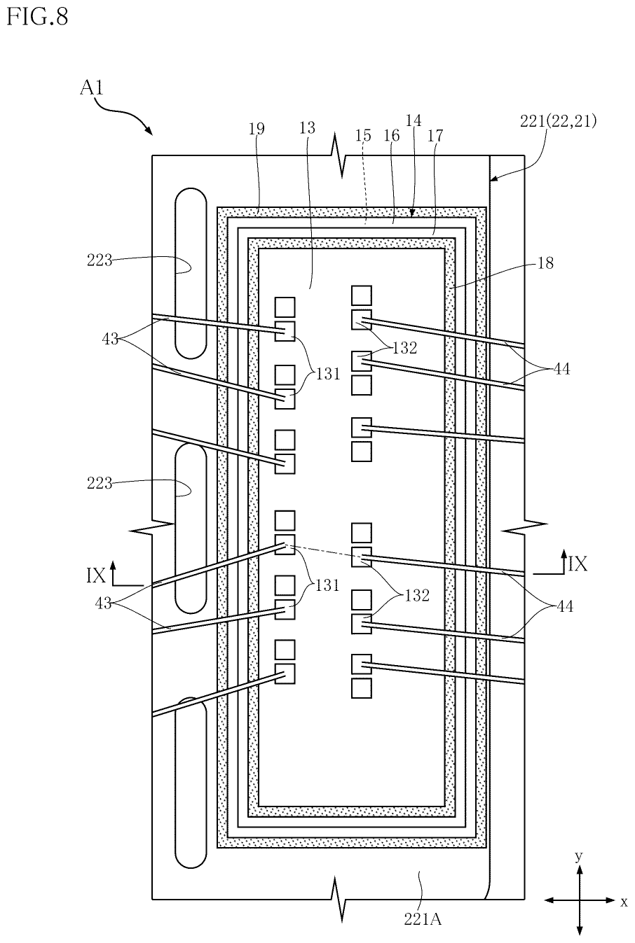

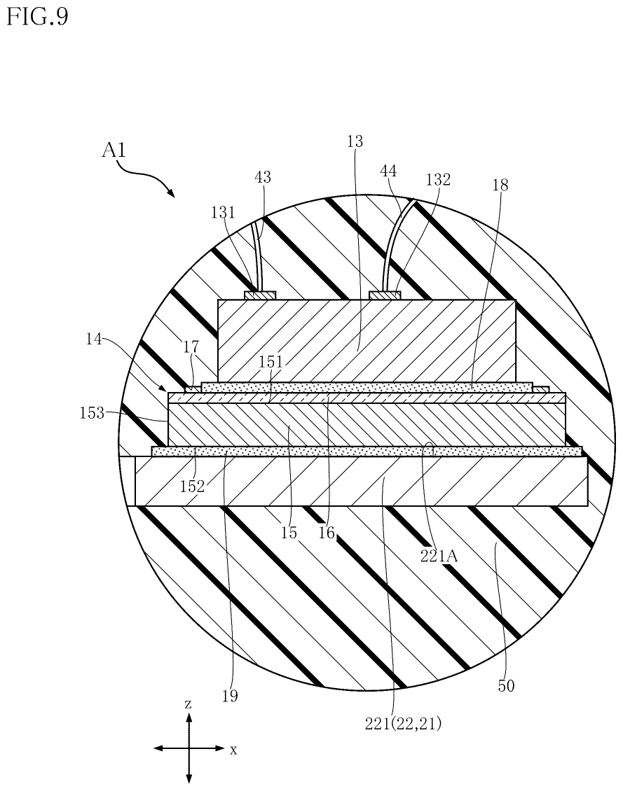

As shown in FIGS. 2 and 6, the insulating element 13 is located between the first semiconductor element 11 and the second semiconductor element 12 in the first direction x. As shown in FIGS. 8 and 9, the insulating element 13 has a plurality of first relay electrodes 131 and a plurality of second relay electrodes 132. The first relay electrodes 131 and the second relay electrodes 132 are on the upper surface (the surface facing in the same direction as the first mounting surface 211A described above) of the insulating element 13. The first relay electrodes 131 are arranged along the second direction y and located closer to the first semiconductor element 11 than to the second semiconductor element 12 in the first direction x. The second relay electrodes 132 are arranged along the second direction y and located closer to the second semiconductor element 12 than to the first semiconductor element 11 in the first direction x.

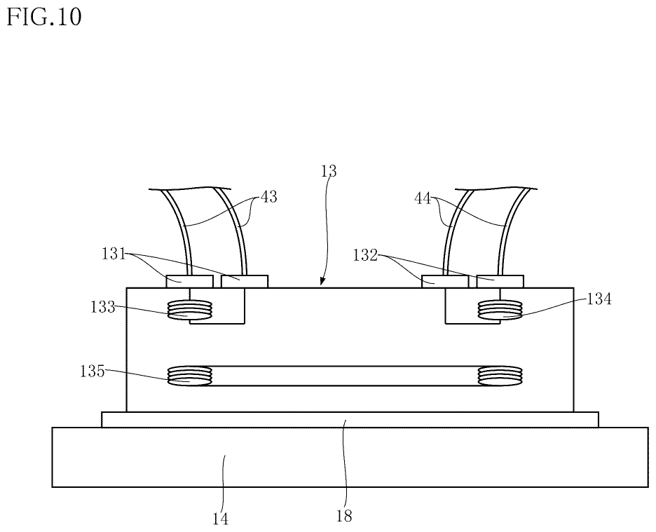

As shown in FIG. 10, the insulating element 13 further has a first transmitter/receiver 133, a second transmitter/receiver 134, and a relay unit 135. The first transmitter/receiver 133, the second transmitter/receiver 134, and the relay unit 135 are inductors. The first transmitter/receiver 133 and the second transmitter/receiver 134 are spaced apart from each other in the first direction x. The first transmitter/receiver 133 is electrically connected to the first relay electrodes 131. The first transmitter/receiver 133 is also electrically connected to the first semiconductor element 11 via the third wires 43. The second transmitter/receiver 134 is electrically connected to the second relay electrodes 132. The second transmitter/receiver 134 is also electrically connected to the second semiconductor element 12 via the fourth wires 44.

As shown in FIG. 10, the relay unit 135 is spaced apart from the first transmitter/receiver 133 and the second transmitter/receiver 134 in the thickness direction z. A dielectric layer (not shown) made of silicon dioxide, for example, is interposed between the relay unit 135 and the first and the second transmitter/receivers 133 and 134. The relay unit 135 transmits/receives signals between the first transmitter/receiver 133 and the second transmitter/receiver 134. In the thickness direction z, the relay unit 135 is located closer to the dummy element 14 than are the first transmitter/receiver 133 and the second transmitter/receiver 134. The potential of the relay unit 135 takes a value between the potential of the first transmitter/receiver 133 and the potential of the second transmitter/receiver 134.

As shown in FIGS. 2 and 6, the second semiconductor element 12 has a plurality of second electrodes 121. The second electrodes 121 are on the upper surface of the second semiconductor element 12 (the surface facing in the same direction as a second mounting surface 231A of a second pad portion 231 of the second die pad 23, described later). The composition of the second electrodes 121 includes aluminum, for example. The second electrodes 121 are electrically connected to the circuit formed in the second semiconductor element 12.

The die pad 21, the first terminals 31, and the second terminals 32 form conduction paths between the wiring board on which the semiconductor device A1 is mounted and the first semiconductor element 11, the insulating element 13 and the second semiconductor element 12. The die pad 21, the first terminals 31 and the second terminals 32 are formed from a same lead frame. The lead frame contains copper in its composition. In the semiconductor device A1, the die pad 21 includes a first die pad 22 and a second die pad 23.

As shown in FIGS. 1 and 2, the first die pad 22 and the second die pad 23 are spaced apart from each other in the first direction x. In the semiconductor device A1, the first semiconductor element 11 is mounted on the first die pad 22, and the second semiconductor element 12 is mounted on the second die pad 23. The voltage applied to the second die pad 23 differs from the voltage applied to the first die pad 22. In the semiconductor device A1, the voltage applied to the second die pad 23 is higher than the voltage applied to the first die pad 22.

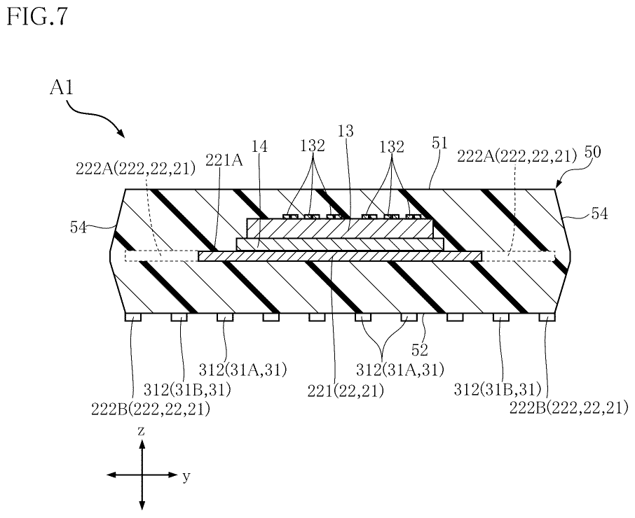

As shown in FIG. 2, the first die pad 22 has the first pad portion 221 and two first suspension lead portions 222. The first semiconductor element 11 is mounted on the first pad portion 221. As shown in FIGS. 6 and 7, the first pad portion 221 has a first mounting surface 221A facing in the thickness direction z. The first semiconductor element 11 is bonded to the first mounting surface 221A via a conductive bonding material (solder, metal paste, etc.), not shown. The first pad portion 221 is covered with the sealing resin 50. The thickness of the first pad portion 221 is 150 μm or more and 200 μm or less, for example.

As shown in FIGS. 2 and 6, the first pad portion 221 is formed with a plurality of through-holes 223. Each of the through-holes 223 penetrates the first pad portion 221 in the thickness direction z and extends in the second direction y. As viewed in the thickness direction z, at least one of the through-holes 223 is located between the first semiconductor element 11 and the dummy element 14. The through-holes 223 are arranged along the second direction y.

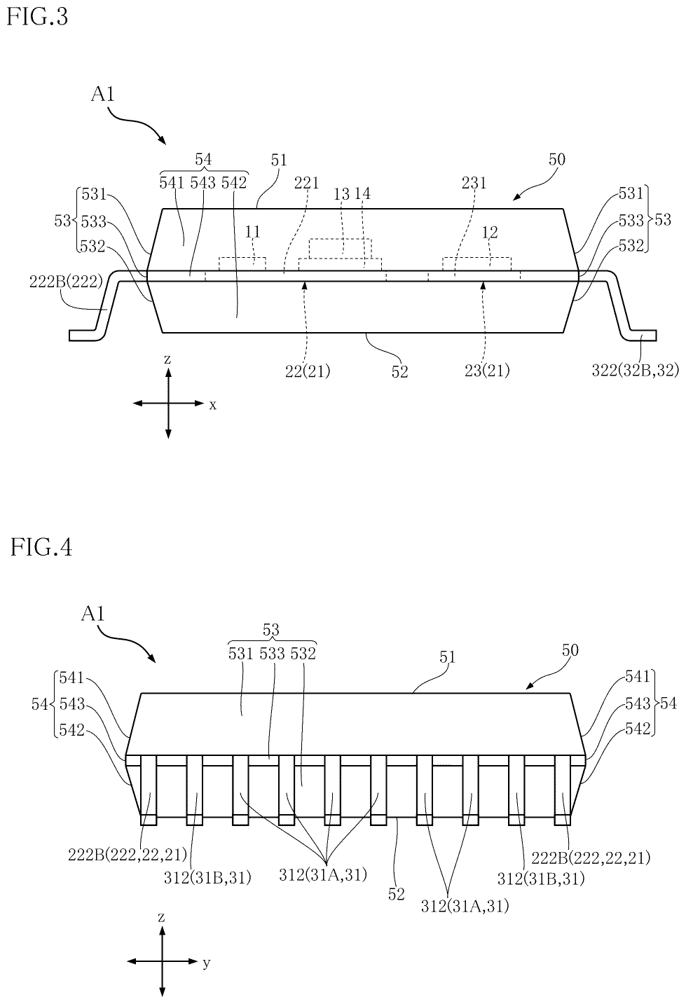

As shown in FIG. 2, the two first suspension lead portions 222 are connected to opposite sides in the second direction y of the first pad portion 221. The two first suspension lead portions 222 each have a covered portion 222A and an exposed portion 222B. The covered portion 222A is connected to the first pad portion 221 and covered with the sealing resin 50. The covered portion 222A includes a section extending in the first direction x. The exposed portion 222B is connected to the covered portion 222A and exposed from the sealing resin 50. As viewed in the thickness direction z, the exposed portion 222B extends in the first direction x. As shown in FIG. 3, the exposed portion 222B is bent into a gull-wing shape as viewed in the second direction y. The surface of the exposed portion 222B may be plated with tin (Sn), for example.

As shown in FIG. 2, the second die pad 23 has a second pad portion 231 and two second suspension lead portions 232. The second semiconductor element 12 is mounted on the second pad portion 231. As shown in FIG. 6, the second pad portion 231 has a second mounting surface 231A facing in the thickness direction z. The second semiconductor element 12 is bonded to the second mounting surface 231A via a conductive bonding material (solder, metal paste, etc.), not shown. The second pad portion 231 is covered with the sealing resin 50. The thickness of the second pad portion 231 is 150 μm or more and 200 μm or less, for example. The area of the second pad portion 231 is smaller than the area of the first pad portion 221 of the first die pad 22. As viewed in the first direction x, the second pad portion 231 overlaps with the first pad portion 221.

As shown in FIG. 2, the two second suspension lead portions 232 extend outward from opposite sides in the second direction y of the second pad portion 231. The two second suspension lead portions 232 each have a covered portion 232A and an exposed portion 232B. The covered portion 232A is connected to the second pad portion 231 and covered with the sealing resin 50. The covered portion 232A includes a section extending in the first direction x. The exposed portion 232B is connected to the covered portion 232A and exposed from the sealing resin 50. As viewed in the thickness direction z, the exposed portion 232B extends in the first direction x. As shown in FIG. 3, the exposed portion 232B is bent into a gull-wing shape as viewed in the second direction y. The surface of the exposed portion 232B may be plated with tin, for example.

As shown in FIGS. 2, 6 and 7, the dummy element 14 is bonded to the die pad 21. As viewed in the thickness direction z, the dummy element 14 is located inward from the periphery of the die pad 21. In the semiconductor device A1, the dummy element 14 is bonded to the first mounting surface 221A of the first pad portion 221 of the first die pad 22. The insulating element 13 is bonded to the dummy element 14.

As shown in FIG. 9, the first bonding layer 18 bonds the dummy element 14 and the insulating element 13. The first bonding layer 18 is a conductor. The first bonding layer 18 is made of, for example, a die attach adhesive. The first bonding layer 18 may be an insulator.

As shown in FIG. 9, the second bonding layer 19 bonds the die pad 21 and the dummy element 14. The second bonding layer 19 is a conductor. The second bonding layer 19 is made of the same material as that of the first bonding layer 18.

As shown in FIGS. 8 and 9, the dummy element 14 includes a semiconductor substrate 15 and an insulating layer 16. The insulating layer 16 is layered on the semiconductor substrate 15. The semiconductor substrate 15 is made of, for example, a silicon wafer containing a p-type dopant. The insulating layer 16 is made of an insulating material selected from silicon dioxide, silicon nitride (Si₃N₄), and polyimide, for example. The insulating layer 16 is located between the die pad 21 and the first bonding layer 18 in the thickness direction z.

As shown in FIG. 9, the semiconductor substrate 15 has a first surface 151, a second surface 152, and a third surface 153. The first surface 151 faces in the thickness direction z and is opposed to the first bonding layer 18. The second surface 152 faces away from the first surface 151 in the thickness direction z and is opposed to the second bonding layer 19. The third surface 153 faces in a direction orthogonal to the thickness direction z. In the semiconductor device A1, the insulating layer 16 is layered on the first surface 151. Thus, the insulating layer 16 is located between the semiconductor substrate 15 and the first bonding layer 18. The insulating layer 16 is in contact with the first bonding layer 18.

As shown in FIGS. 8 and 9, the dummy element 14 is formed with a protrusion 17 protruding from the insulating layer 16 in the thickness direction z. The protrusion 17 is located outside the first bonding layer 18 as viewed in the thickness direction z. The protrusion 17 surrounds the first bonding layer 18. The protrusion 17 is an insulator, as with the insulating layer 16. As with the insulating layer 16, the protrusion 17 is made of an insulating material selected from silicon dioxide, silicon nitride, and polyimide, for example. Therefore, the protrusion 17 may be integral with the insulating layer 16. The dimension of the protrusion 17 in the thickness direction z is smaller than the dimension of the first bonding layer 18 in the thickness direction z.

As shown in FIGS. 1 and 2, the first terminals 31 are located opposite to the second semiconductor element 12 with respect to the insulating element 13 in the first direction x. The first terminals 31 are arranged along the second direction y. At least one of the first terminals 31 is electrically connected to the first semiconductor element 11 via a first wire 41. The first terminals 31 are located between the two first suspension lead portions 222 of the first die pad 22 in the second direction y. The plurality of first terminals 31 include a plurality of first intermediate terminals 31A and two first-side terminals 31B. The two first-side terminals 31B are located on opposite sides in the second direction y of the plurality of first intermediate terminals 31A.

As shown in FIGS. 2 and 6, each of the first terminals 31 has a covered portion 311 and an exposed portion 312. The covered portion 311 is covered with the sealing resin 50. The dimension in the first direction x of the covered portion 311 of each of the two first-side terminals 31B is larger than the dimension in the first direction x of the covered portion 311 of each of the first intermediate terminals 31A.

As shown in FIGS. 2 and 6, the exposed portion 312 is connected to the covered portion 311 and exposed from the sealing resin 50. As viewed in the thickness direction z, the exposed portion 312 extends in the first direction x. The exposed portion 312 is bent into a gull-wing shape as viewed in the second direction y. The shape of the exposed portion 312 is the same as that of the exposed portion 222B of each of the two first suspension lead portions 222 of the first die pad 22. The surface of the exposed portion 312 may be plated with tin, for example.

As shown in FIGS. 1 and 2, the second terminals 32 are located opposite to the first semiconductor element 11 with respect to the insulating element 13 in the first direction x. The second terminals 32 are arranged along the second direction y. At least one of the second terminals 32 is electrically connected to the second semiconductor element 12 via a second wire 42. The plurality of second terminals 32 include a plurality of second intermediate terminals 32A and two second-side terminals 32B. The two second suspension lead portions 232 of the second die pad 23 are located on opposite sides in the second direction y of the plurality of second intermediate terminals 32A. The two second-side terminals 32B flank the second intermediate terminals 32A and the two second suspension lead portions 232 in the second direction y.

As shown in FIGS. 2 and 6, each of the second terminals 32 has a covered portion 321 and an exposed portion 322. The covered portion 321 is covered with the sealing resin 50. The dimension in the first direction x of the covered portion 321 of each of the two second-side terminals 32B is larger than the dimension in the first direction x of the covered portion 321 of each of the second intermediate terminals 32A.

As shown in FIGS. 2 and 6, the exposed portion 322 is connected to the covered portion 321 and exposed from the sealing resin 50. As viewed in the thickness direction z, the exposed portion 322 extends in the first direction x. As shown in FIG. 3, the exposed portion 322 is bent into a gull-wing shape as viewed in the second direction y. The shape of the exposed portion 322 is the same as that of the exposed portion 232B of each of the two second suspension lead portions 232 of the second die pad 23. The surface of the exposed portion 322 may be plated with tin, for example.

The first wires 41, the second wires 42, the third wires 43 and the fourth wires 44 form, together with the die pad 21, the first terminals 31 and the second terminals 32, conduction paths for the first semiconductor element 11, the second semiconductor element 12 and the insulating element 13 to perform predetermined functions.

As shown in FIGS. 2 and 6, some of the first wires 41 are bonded to the first electrodes 111 of the first semiconductor element 11 and the covered portions 311 of the first terminal 31. Thus, at least one of the first terminals 31 is electrically connected to the first semiconductor element 11. At least one of the first wires 41 is bonded to one of the first electrodes 111 and one of the covered portions 222A of the two first suspension lead portions 222 of the first die pad 22. Thus, at least one of the two first suspension lead portions 222 is electrically connected to the first semiconductor element 11. With such a configuration, at least one of the two first suspension lead portions 222 forms a ground terminal of the first semiconductor element 11. The composition of the first wires 41 includes gold (Au). Alternatively, the composition of the first wires 41 may include copper.

As shown in FIGS. 2 and 6, some of the second wires 42 are bonded to the second electrodes 121 of the second semiconductor element 12 and the covered portions 321 of the second terminals 32. Thus, at least one of the second terminals 32 is electrically connected to the second semiconductor element 12. At least one of the second wires 42 is bonded to one of the second electrodes 121 and one of the covered portions 232A of the two second suspension lead portions 232 of the second die pad 23. Thus, at least one of the two second suspension lead portions 232 is electrically connected to the second semiconductor element 12. With such a configuration, at least one of the two second suspension lead portions 232 forms a ground terminal of the second semiconductor element 12. The composition of the second wires 42 includes gold. Alternatively, the composition of the second wires 42 may include copper.

As shown in FIGS. 2 and 6, the third wires 43 are bonded to the first relay electrodes 131 of the insulating element 13 and the first electrodes 111 of the first semiconductor element 11. Thus, the first semiconductor element 11 and the insulating element 13 are electrically connected to each other. The third wires 43 are arranged along the second direction y. The composition of the third wires 43 includes gold.

As shown in FIGS. 2 and 6, the fourth wires 44 are bonded to the second relay electrodes 132 of the insulating element 13 and the second electrodes 121 of the second semiconductor element 12. Thus, the second semiconductor element 12 and the insulating element 13 are electrically connected to each other. The fourth wires 44 are arranged along the second direction y. In the semiconductor device A1, the fourth wires 44 extend across the gap between the first pad portion 221 of the first die pad 22 and the second pad portion 231 of the second die pad 23. The composition of the fourth wires 44 includes gold.

As shown in FIG. 1, the sealing resin 50 covers the first semiconductor element 11, the second semiconductor element 12, the insulating element 13, and a part of each of the die pad 21, the first terminals 31 and the second terminals 32. The sealing resin 50 also covers the first wires 41, the second wires 42, the third wires 43, and the fourth wires 44. The sealing resin 50 is electrically insulating. The sealing resin 50 is made of a material containing epoxy resin, for example. The sealing resin 50 is rectangular as viewed in the thickness direction z.

As shown in FIGS. 3 to 5, the sealing resin 50 has a top surface 51, a bottom surface 52, a pair of first side surfaces 53, and a pair of second side surfaces 54.

As shown in FIGS. 3 to 5, the top surface 51 and the bottom surface 52 are spaced apart from each other in the thickness direction z. The top surface 51 and the bottom surface 52 face away from each other in the thickness direction z. Each of the top surface 51 and the bottom surface 52 is flat (or generally flat).

As shown in FIGS. 3 to 5, the pair of first side surfaces 53 are connected to the top surface 51 and the bottom surface 52 and spaced apart from each other in the first direction x. The exposed portions 222B of the two first suspension lead portions 222 of the first die pad 22 and the exposed portions 312 of the first terminals 31 are exposed from the first side surface 53 of the pair of first side surfaces 53 that is located on one side in the first direction x. The exposed portions 232B of the two second suspension lead portions 232 of the second die pad 23 and the exposed portions 322 of the second terminals 32 are exposed from the first side surface 53 of the pair of first side surfaces 53 that is located on the other side in the first direction x.

As shown in FIGS. 3 to 5, each of the pair of first side surfaces 53 includes a first upper portion 531, a first lower portion 532, and a first intermediate portion 533. The first upper portion 531 is connected to the top surface 51 on one side in the thickness direction z and connected to the first intermediate portion 533 on the other side in the thickness direction z. The first upper portion 531 is inclined with respect to the top surface 51. The first lower portion 532 is connected to the bottom surface 52 on one side in the thickness direction z and connected to the first intermediate portion 533 on the other side in the thickness direction z. The first lower portion 532 is inclined with respect to the bottom surface 52. The first intermediate portion 533 is connected to the first upper portion 531 on one side in the thickness direction z and connected to the first lower portion 532 on the other side in the thickness direction z. The in-plane direction of the first intermediate portion 533 is defined by the thickness direction z and the second direction y. The first intermediate portion 533 is located outside the top surface 51 and the bottom surface 52 as viewed in the thickness direction z. The exposed portions 222B of the two first suspension lead portions 222 of the first die pad 22, the exposed portions 232B of the two second suspension lead portions 232 of the second die pad 23, the exposed portions 312 of the first terminals 31, and the exposed portions 322 of the second terminals 32 are exposed from the first intermediate portions 533 of the pair of first side surfaces 53.

As shown in FIGS. 3 to 5, the pair of second side surfaces 54 are connected to the top surface 51 and the bottom surface 52 and spaced apart from each other in the second direction y. As shown in FIG. 1, the first die pad 22, the second die pad 23, the first terminals 31, and the second terminals 32 are spaced apart from the pair of second side surfaces 54.

As shown in FIGS. 3 to 5, each of the pair of second side surfaces 54 includes a second upper portion 541, a second lower portion 542, and a second intermediate portion 543. The second upper portion 541 is connected to the top surface 51 on one side in the thickness direction z and connected to the second intermediate portion 543 on the other side in the thickness direction z. The second upper portion 541 is inclined with respect to the top surface 51. The second lower portion 542 is connected to the bottom surface 52 on one side in the thickness direction z and connected to the second intermediate portion 543 on the other side in the thickness direction z. The second lower portion 542 is inclined with respect to the bottom surface 52. The second intermediate portion 543 is connected to the second upper portion 541 on one side in the thickness direction z and connected to the second lower portion 542 on the other side in the thickness direction z. The in-plane direction of the second intermediate portion 543 is defined by the thickness direction z and the first direction x. The second intermediate portion 543 is located outside the top surface 51 and the bottom surface 52 as viewed in the thickness direction z.

Generally, in a motor driver circuit for an inverter device, a half-bridge circuit is built that includes a low-side (low-potential side) switching element and a high-side (high-potential side) switching element. An example in which these switching elements are MOSFETs will be described. In the low-side switching element, the reference potentials of the source of the switching element and the gate driver that drives the switching element are both ground. In contrast, in the high-side switching element, the reference potentials of the source of the switching element and the gate driver that drives the switching element both correspond to the potential at the output node of the half-bridge circuit. Because the potential at the output node changes in response to the operation of the high-side switching element and the low-side switching element, the reference potential of the gate driver that drives the high-side switching element changes. When the high-side switching element is ON, the reference potential is equivalent to the voltage applied to the drain of the high-side switching element (e.g., 600 V or higher). In semiconductor device A1, the ground of the first semiconductor element 11 and the ground of the second semiconductor element 12 are separated. Thus, when the semiconductor device A1 is used as a gate driver for driving the high-side switching element, a voltage equivalent to the voltage applied to the drain of the high-side switching element is transiently applied to the ground of the second semiconductor element 12.

First Variation of the First Embodiment

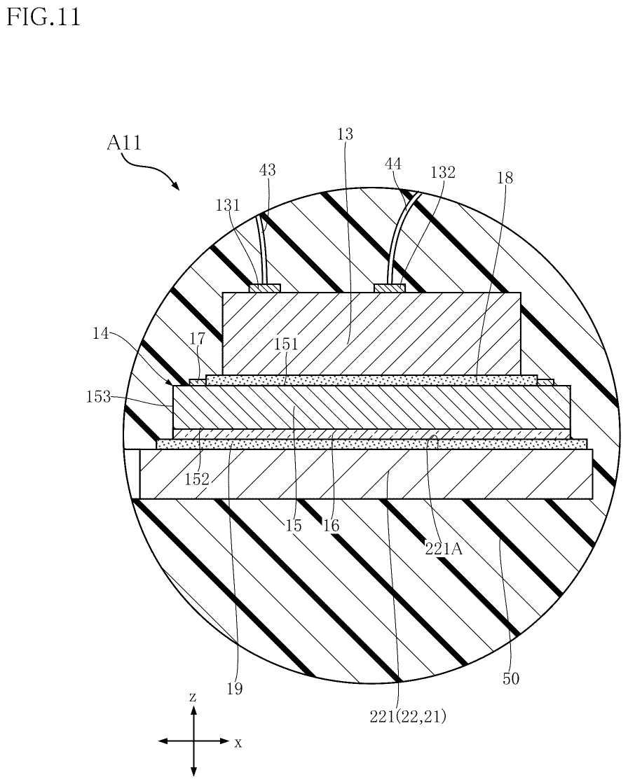

Next, a semiconductor device A11, which is a first variation of the semiconductor device A1, will be described based on FIG. 11. The semiconductor device A11 differs from the semiconductor device A1 in configuration of the dummy element 14. FIG. 11 is a sectional view taken along the same plane as FIG. 9.

In the semiconductor device A1, the insulating layer 16 is layered on the second surface 152 of the semiconductor substrate 15 as shown in FIG. 11. Thus, the insulating layer 16 is located between the second bonding layer 19 and the semiconductor substrate 15 in the thickness direction z. The insulating layer 16 is in contact with the second bonding layer 19. The protrusion 17 is formed in contact with the first surface 151 of the semiconductor substrate 15.

### Second Variation of the First Embodiment

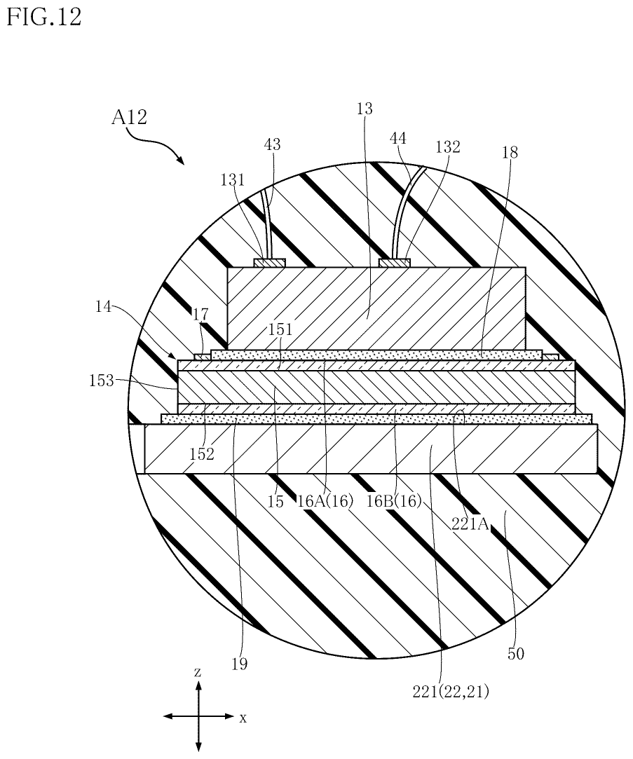

Next, a semiconductor device A12, which is a second variation of the semiconductor device A1, will be described based on FIG. 12. The semiconductor device A12 differs from the semiconductor device A1 in configuration of the dummy element 14. FIG. 12 is a sectional view taken along the same plane as FIG. 9.

In the semiconductor device A12, the insulating layer 16 includes a first layer 16A and a second layer 16B as shown in FIG. 12. The second layer 16B is spaced apart from the first layer 16A in the thickness direction z. The first layer 16A is layered on the first surface 151 of the semiconductor substrate 15. Thus, the first layer 16A is located between the semiconductor substrate 15 and the first bonding layer 18 in the thickness direction z. The first layer 16A is in contact with the first bonding layer 18. The second layer 16B is layered on the second surface 152 of the semiconductor substrate 15. Thus, the second layer 16B is located between the second bonding layer 19 and the semiconductor substrate 15 in the thickness direction z. The second layer 16B is in contact with the second bonding layer 19.

### Third Variation of the First Embodiment

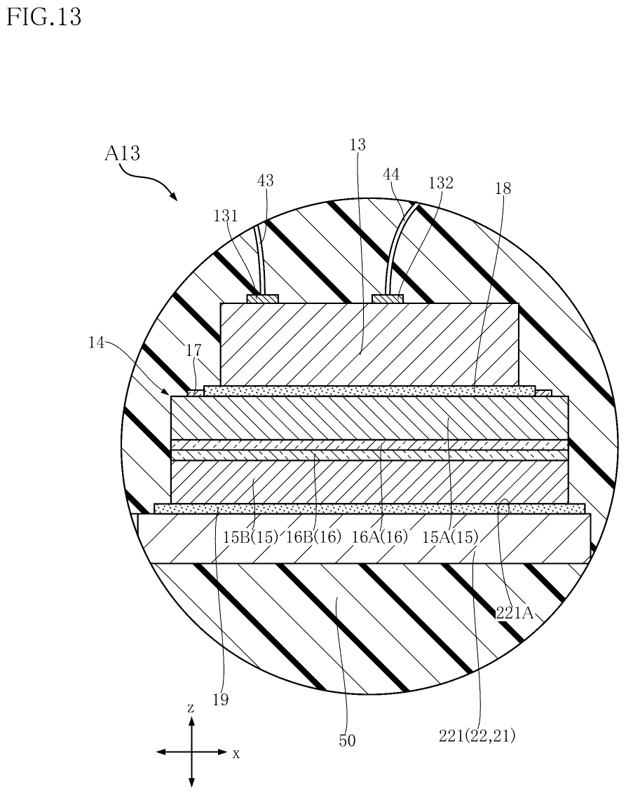

Next, a semiconductor device A13, which is a third variation of the semiconductor device A1, will be described based on FIG. 13. The semiconductor device A13 differs from the semiconductor device A1 in configuration of the dummy element 14. FIG. 13 is a sectional view taken along the same plane as FIG. 9.

In the semiconductor device A13, the semiconductor substrate 15 includes a first substrate 15A and a second substrate 15B as shown in FIG. 13. The second substrate 15B is spaced apart from the first substrate 15A in the thickness direction z. The first substrate 15A is in contact with the first bonding layer 18. The second substrate 15B is located between the second bonding layer 19 and the first substrate 15A in the thickness direction z and in contact with the second bonding layer 19. The insulating layer 16 is located between the second substrate 15B and the first substrate 15A in the thickness direction z. The insulating layer 16 includes a first layer 16A layered on the first substrate 15A and a second layer 16B layered on the second substrate 15B. The second layer 16B faces the first layer 16A. Alternatively, the insulating layer 16 may have a single-piece structure that does not include the first layer 16A and the second layer 16B.

Next, the effects of the semiconductor device A1 will be described.

The semiconductor device A1 includes the die pad 21, the first semiconductor element 11 and the second semiconductor element 12 each mounted on the die pad 21, and the insulating element 13 that insulates the first semiconductor element 11 and the second semiconductor element 12 from each other. The semiconductor device A1 further includes the dummy element 14 bonded to the die pad 21, and the first bonding layer 18 that bonds the dummy element 14 and the insulating element 13. The dummy element 14 includes the insulating layer 16 located between the die pad 21 and the first bonding layer 18 in the thickness direction z. Dielectric breakdown of the insulating element 13 can occur when charged carriers move from the die pad 21 to the insulating element 13. According to the present configuration, the insulating layer 16 hinders movement of such carriers from the upper surface of the die pad 21 (the first mounting surface 221A of the first pad portion 221 of the first die pad 22) to the lower surface of the insulating element 13 that f faces the upper surface. This makes dielectric breakdown of the insulating element 13 less likely to occur. Thus, the semiconductor device A1 is capable of improving the dielectric strength between the die pad 21, on which the semiconductor elements (the first semiconductor element 11 and the second semiconductor element 12) are mounted, and the insulating element 13.

The dummy element 14 includes the semiconductor substrate 15 in addition to the insulating layer 16. The insulating layer 16 is layered on the semiconductor substrate 15. Such a configuration allows the use of a same mounting device for the process of bonding the dummy element 14 to the die pad 21 via the second bonding layer 19 and the process of bonding the insulating element 13 to the dummy element 14 via the first bonding layer 18. This allows for labor saving in the manufacturing equipment of semiconductor device A1.

In the semiconductor device A12, the insulating layer 16 includes the first layer 16A and the second layer 16B spaced apart from the first layer 16A. The first layer 16A is located between the semiconductor substrate 15 and the first bonding layer 18. The second layer 16B is located between the second bonding layer 19 and the semiconductor substrate 15. With such a configuration, charged carriers are more effectively blocked by the insulating layer 16 as compared with the configuration of the semiconductor device A1. This configuration is particularly effective in the case where the first bonding layer 18 is a conductor in contact with the first layer 16A and the second bonding layer 19 is a conductor in contact with the second layer 16B.

The dummy element 14 is formed with the protrusion 17 protruding from the insulating layer 16 in the thickness direction z. As viewed in the thickness direction z, the protrusion 17 is located outside the first bonding layer 18. With such a configuration, when the insulating element 13 is bonded to the dummy element 14 via the first bonding layer 18, the spread of the first bonding layer 18 is constrained by the protrusion 17. Thus, the first bonding layer 18 is prevented from reaching the third surface 153 of the semiconductor substrate 15. When the protrusion 17 surrounds the first bonding layer 18, such an effect to be exhibited more effectively. This configuration is particularly effective in the case where the first bonding layer 18 is a conductor in contact with the insulating layer 16.

The insulating element 13 has the first transmitter/receiver 133, the second transmitter/receiver 134, and the relay unit 135. In the thickness direction z, the relay unit 135 is located closer to the dummy element 14 than are the first transmitter/receiver 133 and the second transmitter/receiver 134. Such a configuration allows the potential difference between the first transmitter/receiver 133 and the relay unit 135 and the potential difference between the second transmitter/receiver 134 and the relay unit 135 to be set small in the insulating element 13. This allows improvement of the dielectric strength of the insulating element 13. Moreover, the potential difference between the upper surface of the die pad 21 and the lower surface of the insulating element 13 is reduced. This leads to more effective improvement of the dielectric strength between the die pad 21 and the insulating element 13.

The dummy element 14 is located inward from the periphery of the die pad 21 as viewed in the thickness direction z. This prevents an increase in size of the semiconductor device A1.

In the semiconductor device A1, each of the die pad 21, first terminals 31 and second terminals 32 is partially exposed from either one of the pair of first side surfaces 53 of the sealing resin 50. Such a configuration is realized by the two first suspension lead portions 222 of the first die pad 22 being exposed from one side of the sealing resin 50 in the first direction x and the two second suspension lead portions 232 of the second die pad 23 being exposed at the other side of the sealing resin 50 in the first direction x. With such a configuration, the die pad 21, the first terminals 31, and the second terminals 32 are spaced apart from the pair of second side surfaces 54 of the sealing resin 50. Thus, none of the die pad 21, the first terminals 31, and the second terminals 32 are exposed from the pair of second side surfaces 54. This contributes to improvement of the dielectric strength of the semiconductor device A1.

In the semiconductor device A1, the first pad portion 221 of the first die pad 22, which is larger in area than the second pad portion 231 of the second die pad 23, is formed with the through-holes 223. This allows the fluidized sealing resin 50 to pass through these through-holes 223 during the manufacture of the semiconductor device A1, whereby poor filling of the sealing resin 50 is prevented. Thus, generation of voids in the sealing resin 50 is effectively suppressed. This contributes to prevention of decrease in the dielectric strength of the semiconductor device A1.

### Second Embodiment

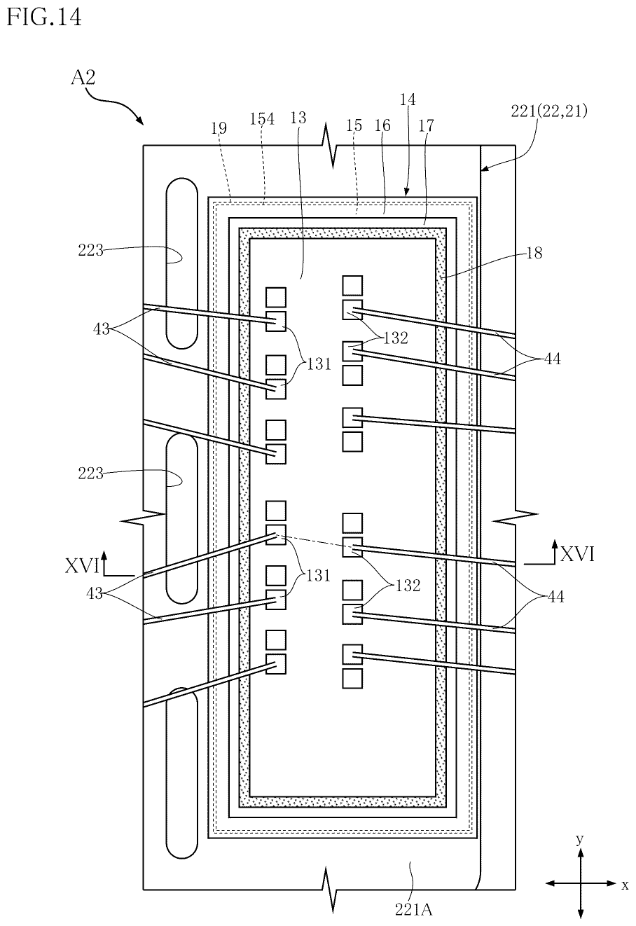

A semiconductor device A2 according to a second embodiment of the present disclosure will be described based in FIGS. 14 to 16. In these figures, the elements that are identical or similar to those of the above-described semiconductor device A1 are denoted by the same reference signs, and the descriptions thereof are omitted. For convenience of understanding, illustration of the sealing resin 50 is omitted in FIG. 14.

The semiconductor device A2 differs from the semiconductor device A1 in configuration of the dummy element 14.

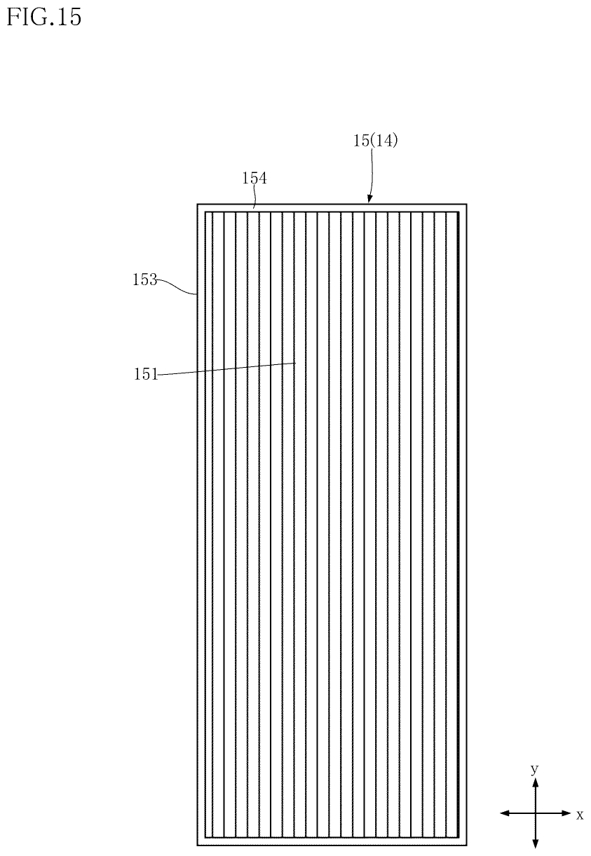

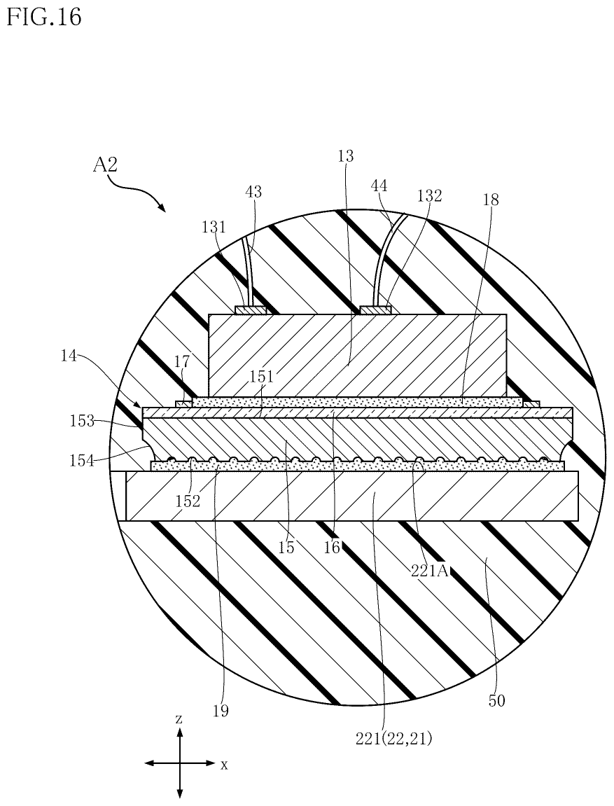

As shown in FIGS. 15 and 16, the semiconductor substrate 15 is formed with a first recess 154. The first recess 154 is recessed from the second surface 152 and the third surface 153 of the semiconductor substrate 15. The first recess 154 surrounds the second surface 152. The first recess 154 can be formed by performing half-cut dicing on the silicon wafer that is the base of the semiconductor substrate 15.

As shown in FIG. 16, the surface roughness of the second surface 152 of the semiconductor substrate 15 is larger than the surface roughness of the third surface 153 of the semiconductor substrate 15. The second surface 152 having such a structure is obtained by performing mechanical grinding on the silicon wafer that is the base of the semiconductor substrate 15.

As shown in FIG. 14, the second bonding layer 19 is surrounded by the periphery of the dummy element 14 as viewed in the thickness direction z.

Next, the effects of the semiconductor device A2 will be described.

The semiconductor device A2 includes the die pad 21, the first semiconductor element 11 and the second semiconductor element 12 each mounted on the die pad 21, and the insulating element 13 that insulates the first semiconductor element 11 and the second semiconductor element 12 from each other. The semiconductor device A2 further includes the dummy element 14 bonded to the die pad 21, and the first bonding layer 18 that bonds the dummy element 14 and the insulating element 13. The dummy element 14 includes the insulating layer 16 located between the die pad 21 and the first bonding layer 18 in the thickness direction z. Thus, the semiconductor device A2 is also capable of improving the dielectric strength between the die pad 21, on which the semiconductor elements (the first semiconductor element 11 and the second semiconductor element 12) are mounted, and the insulating element 13. The semiconductor device A2 has a configuration in common with the semiconductor device A1, thereby achieving the same effect as the semiconductor device A1.

In the semiconductor device A2, the semiconductor substrate 15 is formed with the first recess 154 recessed from the second surface 152 and the third surface 153. Such a configuration increases the creepage distance of the dummy element 14 (the distance along the surface of the dummy element 14) from the first bonding layer 18 to the second bonding layer 19. As a result, the travel distance of charged carriers from the upper surface of the die pad 21 to the lower surface of the insulating element 13 becomes longer, whereby the dielectric strength between the die pad 21 and the insulating element 13 is further improved as compared with the configuration of the semiconductor device A1. When the first recess 154 surrounds the second surface 152, such an effect is exhibited more effectively.

The second bonding layer 19 is surrounded by the periphery of the dummy element 14 as viewed in the thickness direction z. Such a configuration is obtained by the first recess 154 preventing the second bonding layer 19 from rising to the dummy element 14 when the dummy element 14 is bonded to the die pad 21 via the second bonding layer 19. By preventing the second bonding layer 19 from rising to the dummy element 14, shortening of the creepage distance of the dummy element 14 from the first bonding layer 18 to the second bonding layer 19 can be avoided. This configuration is particularly effective in the case where the second bonding layer 19 is a conductor in contact with the semiconductor substrate 15.

The surface roughness of the second surface 152 of the semiconductor substrate 15 is larger than the surface roughness of the third surface 153 of the semiconductor substrate 15. With such a configuration, the second bonding layer 19 may exhibit anchoring effect on the semiconductor substrate 15. Thus, the bonding strength of the dummy element 14 to the die pad 21 can be improved.

### Third Embodiment

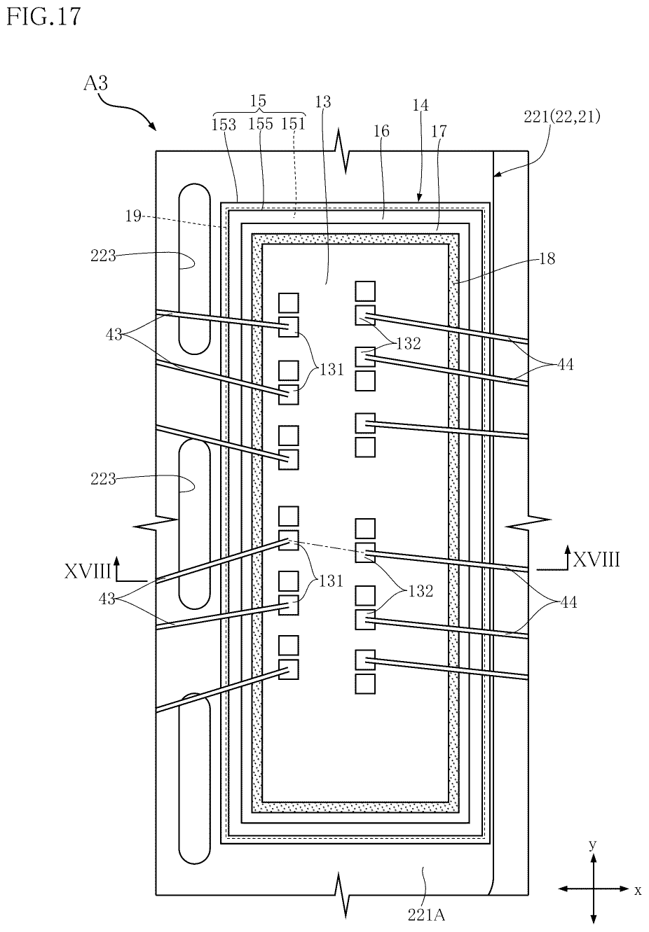

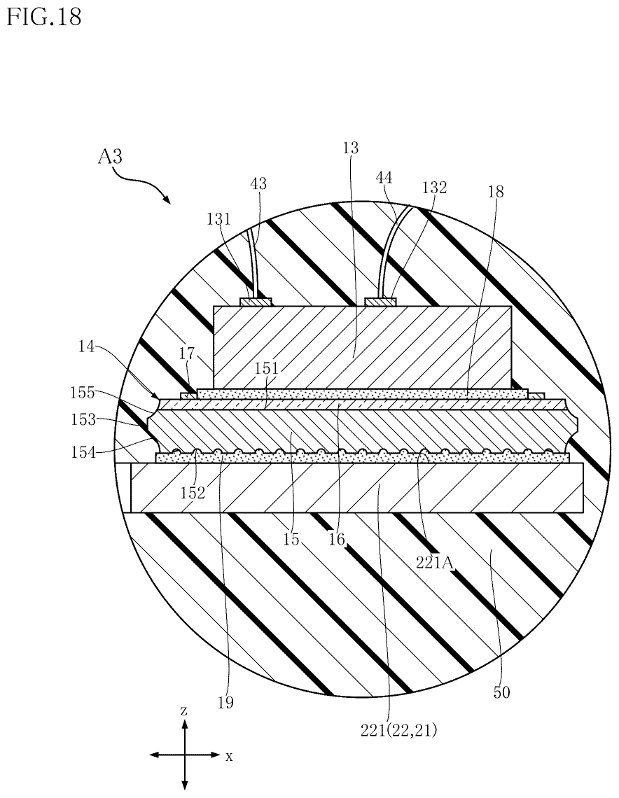

A semiconductor device A3 according to a third embodiment of the present disclosure will be described based in FIGS. 17 and 18. In these figures, the elements that are identical or similar to those of the above-described semiconductor device A1 are denoted by the same reference signs, and the descriptions thereof are omitted. For convenience of understanding, illustration of the sealing resin 50 is omitted in FIG. 17.

The semiconductor device A3 differs from the above-described semiconductor device A2 in configuration of the dummy element 14.

As shown in FIG. 18, the semiconductor substrate 15 is formed with a second recess 155 in addition to the first recess 154. The configuration of the first recess 154 is the same as that of the semiconductor device A2. The second recess 155 is recessed from the first surface 151 and the third surface 153 of the semiconductor substrate 15. The second recess 155 overlaps with the first recess 154 as viewed in the thickness direction z. As shown in FIG. 17, the second recess 155 surrounds the first surface 151. The first recess 154 and the second recess 155 can be formed by performing half-cut dicing on the silicon wafer that is the base of the semiconductor substrate 15.

Next, the effects of the semiconductor device A3 will be described.

The semiconductor device A3 includes the die pad 21, the first semiconductor element 11 and the second semiconductor element 12 each mounted on the die pad 21, and the insulating element 13 that insulates the first semiconductor element 11 and the second semiconductor element 12 from each other. The semiconductor device A3 further includes the dummy element 14 bonded to the die pad 21, and the first bonding layer 18 that bonds the dummy element 14 and the insulating element 13. The dummy element 14 includes the insulating layer 16 located between the die pad 21 and the first bonding layer 18 in the thickness direction z. Thus, the semiconductor device A3 is also capable of improving the dielectric strength between the die pad 21, on which the semiconductor elements (the first semiconductor element 11 and the second semiconductor element 12) are mounted, and the insulating element 13. The semiconductor device A3 has a configuration in common with the semiconductor device A1, thereby achieving the same effect as the semiconductor device A1.

In the semiconductor device A3, the semiconductor substrate 15 is formed with the first recess 154 recessed from the second surface 152 and the third surface 153, and the second recess 155 recessed from the first surface 151 and the third surface 153. The second recess 155 overlaps with the first recess 154 as viewed in the thickness direction z. Such a configuration makes the creepage distance of the dummy element 14 from the first bonding layer 18 to the second bonding layer 19 longer than that in the configuration of the semiconductor device A2. As a result, the travel distance of charged carriers from the upper surface of the die pad 21 to the lower surface of the insulating element 13 becomes further longer, which further improves the dielectric strength between the die pad 21 and the insulating element 13 as compared with the configuration of the semiconductor device A1. When the first recess 154 surrounds the first surface 151, such an effect is exhibited more effectively.

### Fourth Embodiment

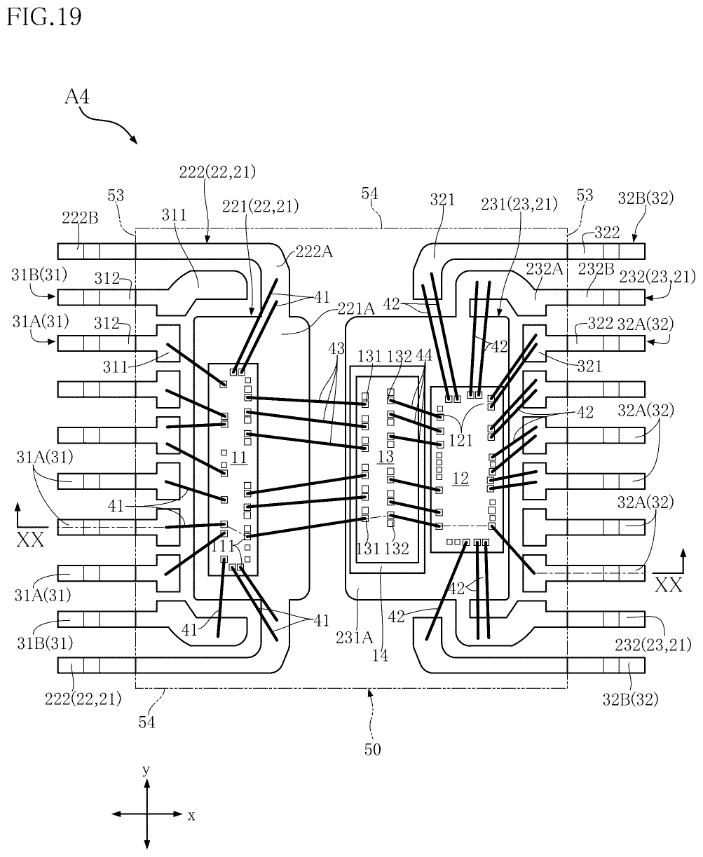

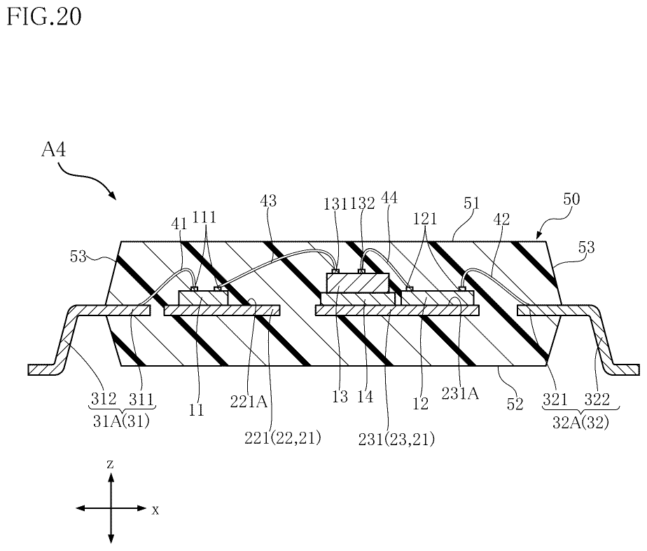

A semiconductor device A4 according to a fourth embodiment of the present disclosure will be described based in FIGS. 19 and 20. In these figures, the elements that are identical or similar to those of the above-described semiconductor device A1 are denoted by the same reference signs, and the descriptions thereof are omitted. FIG. 19 illustrates the sealing resin 50 only in its outlines for convenience of understanding. In FIG. 19, the outlines of the sealing resin 50 are shown by imaginary lines.

The semiconductor device A4 from the differs semiconductor device A1 in configurations of the insulating element 13 and the dummy element 14.

As shown in FIGS. 19 and 20, the dummy element 14 is bonded to the second mounting surface 231A of the second pad portion 231 of the second die pad 23. Thus, the insulating element 13 is located on the second pad portion 231 together with the second semiconductor element 12. As with the semiconductor device A1, the dummy element 14 is bonded to the second mounting surface 231A via the second bonding layer 19 (see FIG. 9). Also, as with the semiconductor device A1, the insulating element 13 is bonded to the dummy element 14 via the first bonding layer 18. In the semiconductor device A4, therefore, the third wires 43 extend across the gap between the first pad portion 221 of the first die pad 22 and the second pad portion 231. Thus, the insulating element 13 can be mounted on the second pad portion 231 in the case where the potential of the second pad portion 231 is higher than the potential of the first pad portion 221 as well.

Next, the effects of the semiconductor device A4 will be described.

The semiconductor device A4 includes the die pad 21, the first semiconductor element 11 and the second semiconductor element 12 each mounted on the die pad 21, and the insulating element 13 that insulates the first semiconductor element 11 and the second semiconductor element 12 from each other. The semiconductor device A4 further includes the dummy element 14 bonded to the die pad 21, and the first bonding layer 18 that bonds the dummy element 14 and the insulating element 13. The dummy element 14 includes the insulating layer 16 located between the die pad 21 and the first bonding layer 18 in the thickness direction z. Thus, the semiconductor device A4 is also capable of improving the dielectric strength between the die pad 21, on which the semiconductor elements (the first semiconductor element 11 and the second semiconductor element 12) are mounted, and the insulating element 13. The semiconductor device A4 has a configuration in common with the semiconductor device A1, thereby achieving the same effect as the semiconductor device A1.

### Fifth Embodiment

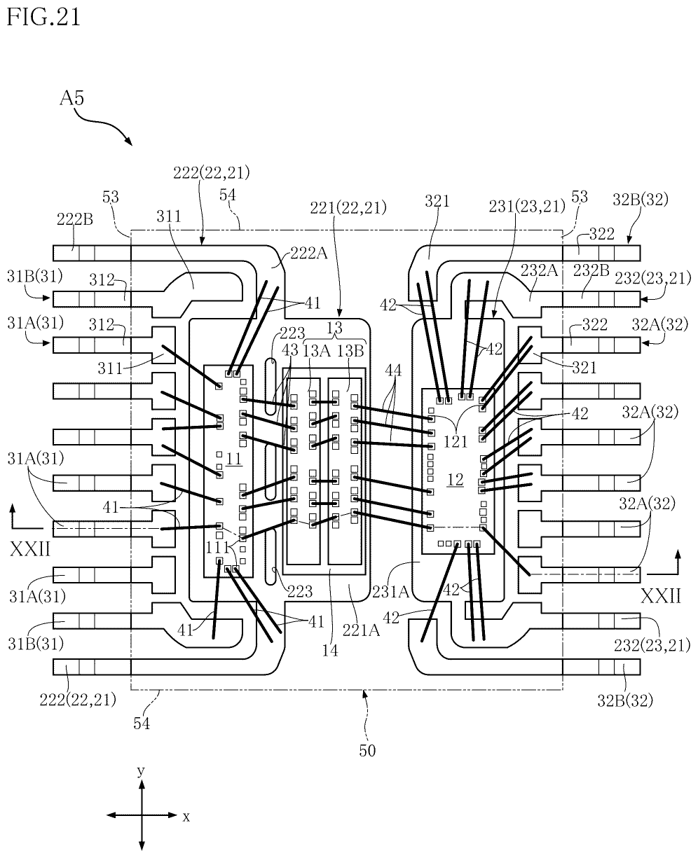

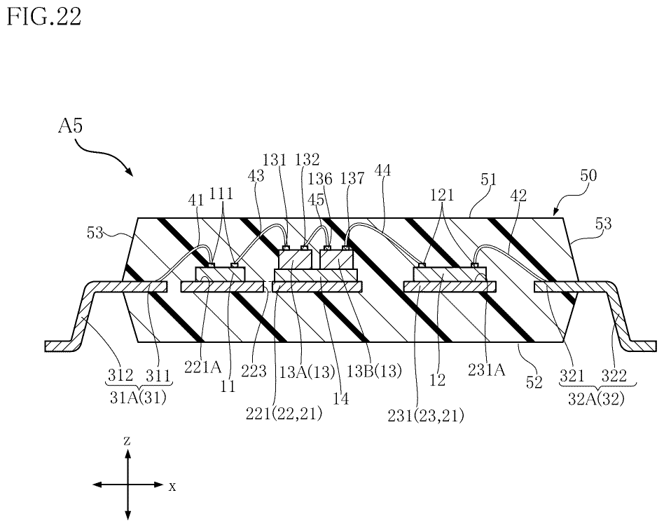

A semiconductor device A5 according to a fifth embodiment of the present disclosure will be described based in FIGS. 21 to 25. In these figures, the elements that are identical or similar to those of the above-described semiconductor device A1 are denoted by the same reference signs, and the descriptions thereof are omitted. FIG. 21 illustrates the sealing resin 50 only in its outlines for convenience of understanding. In FIG. 21, the outlines of the sealing resin 50 are shown by imaginary lines.

The semiconductor device A5 differs the from semiconductor device A1 in configuration of the insulating element 13. The semiconductor device A5 further includes a plurality of fifth wires 45.

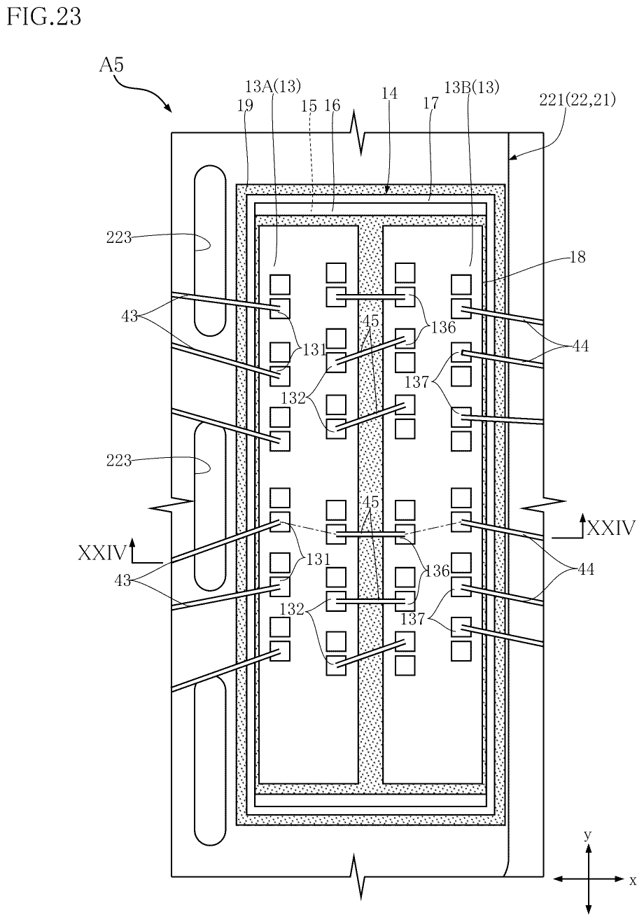

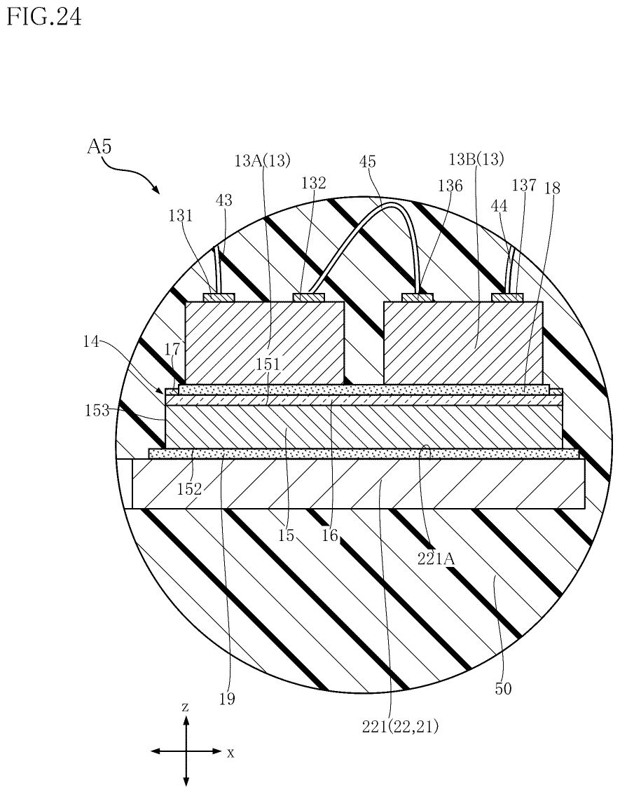

As shown in FIGS. 21 to 24, the insulating element 13 includes a first insulating element 13A and a second insulating element 13B that are spaced apart from each other. In the semiconductor device A5, the first insulating element 13A and the second insulating element 13B are spaced apart from each other in the first direction x such that the first insulating element 13A is closer to the first semiconductor element 11 than is the second insulating element 13B. The first insulating element 13A and the second insulating element 13B are bonded to the dummy element 14 via the first bonding layer 18. As shown in FIGS. 23 and 24, in the semiconductor device A5, the first bonding layer 18 is a single layer. Alternatively, the first bonding layer 18 may be made up of separate portions similarly to the first insulating element 13A and the second insulating element 13B. In the semiconductor device A5, the dummy element 14 is bonded to the first mounting surface 221A of the first pad portion 221 of the first die pad 22 via the second bonding layer 19. Alternatively, the dummy element 14 may be bonded to the second mounting surface 231A of the second pad portion 231 of the second die pad 23 as with the above-described semiconductor device A4.

As shown in FIG. 23, the first insulating element 13A has a plurality of first relay electrodes 131 and a plurality of second relay electrodes 132. The third wires 43 are bonded to the first relay electrodes 131 and the first electrodes 111 of the first semiconductor element 11. Thus, the first relay electrodes 131 are electrically connected to the first semiconductor element 11.

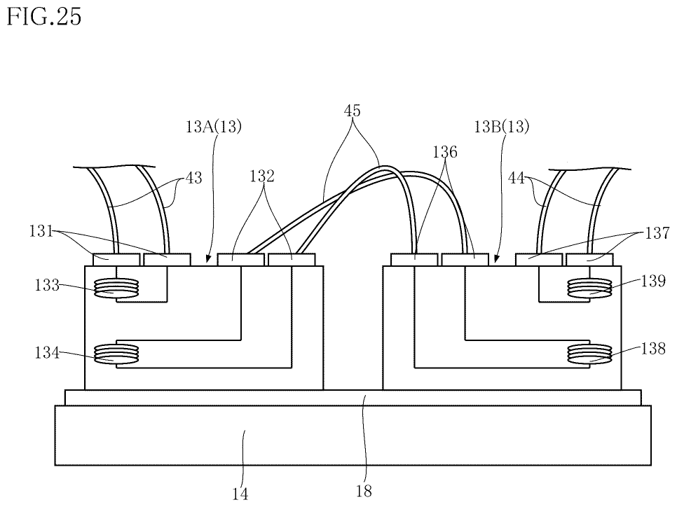

As shown in FIG. 25, the first insulating element 13A has a first transmitter/receiver 133 and a second transmitter/receiver 134. In the semiconductor device A5, the first transmitter/receiver 133 and the second transmitter/receiver 134 are inductors. The first transmitter/receiver 133 and the second transmitter/receiver 134 are spaced apart from each other in the thickness direction z. In the first insulating element 13A, a dielectric layer (not shown) made of silicon dioxide, for example, is interposed between the first transmitter/receiver 133 and the second transmitter/receiver 134. The first transmitter/receiver 133 is electrically connected to the first relay electrodes 131. Thus, the first transmitter/receiver 133 is electrically connected to the first semiconductor element 11. The second transmitter/receiver 134 transmits/receives signals to/from the first transmitter/receiver 133. The second transmitter/receiver 134 is electrically connected to the second relay electrodes 132. In the thickness direction z, the second transmitter/receiver 134 is located closer to the dummy element 14 than is the first transmitter/receiver 133.

As shown in FIG. 23, the second insulating element 13B has a plurality of third relay electrodes 136 and a plurality of fourth relay electrodes 137. The fourth wires 44 are bonded to the fourth relay electrodes 137 and the second electrodes 121 of the second semiconductor element 12. Thus, the fourth relay electrodes 137 are electrically connected to the second semiconductor element 12.

As shown in FIG. 25, the second insulating element 13B has a third transmitter/receiver 138 and a fourth transmitter/receiver 139. In the semiconductor device A5, the third transmitter/receiver 138 and the fourth transmitter/receiver 139 are inductors. The third transmitter/receiver 138 and the fourth transmitter/receiver 139 are spaced apart from each other in the thickness direction z. In the second insulating element 13B, a dielectric layer (not shown) made of silicon dioxide, for example, is interposed between the third transmitter/receiver 138 and the fourth transmitter/receiver 139. The fourth transmitter/receiver 139 is electrically connected to the fourth relay electrodes 137. Thus, the fourth transmitter/receiver 139 is electrically connected to the second semiconductor element 12. The third transmitter/receiver 138 transmits/receives signals to/from the fourth transmitter/receiver 139. The third transmitter/receiver 138 is electrically connected to the third relay electrodes 136. In the thickness direction z, the third transmitter/receiver 138 is located closer to the dummy element 14 than is the fourth transmitter/receiver 139.

As shown in FIGS. 23 and 24, the fifth wires 45 are bonded to the third relay electrodes 136 of the second insulating element 13B and the first relay electrodes 131 of the first insulating element 13A. The composition of the fifth wires 45 includes gold. In this way, the second relay electrodes 132 and the third relay electrodes 136 are electrically connected to each other. Thus, the third transmitter/receiver 138 of the second insulating element 13B is electrically connected to the second transmitter/receiver 134 of the first insulating element 13A. Therefore, the potential of the third transmitter/receiver 138 is equal to the potential of the second transmitter/receiver 134. Thus, the potential of the second transmitter/receiver 134 and the third transmitter/receiver 138 takes a value between the potential of the first transmitter/receiver 133 of the first insulating element 13A and the potential of the fourth transmitter/receiver 139 of the second insulating element 13B.

Next, the effects of the semiconductor device A5 will be described.

The semiconductor device A5 includes the die pad 21, the first semiconductor element 11 and the second semiconductor element 12 each mounted on the die pad 21, and the insulating element 13 that insulates the first semiconductor element 11 and the second semiconductor element 12 from each other. The semiconductor device A5 further includes the dummy element 14 bonded to the die pad 21, and the first bonding layer 18 that bonds the dummy element 14 and the insulating element 13. The dummy element 14 includes the insulating layer 16 located between the die pad 21 and the first bonding layer 18 in the thickness direction z. Thus, the semiconductor device A5 is also capable of improving the dielectric strength between the die pad 21, on which the semiconductor elements (the first semiconductor element 11 and the second semiconductor element 12) are mounted, and the insulating element 13. The semiconductor device A5 has a configuration in common with the semiconductor device A1, thereby achieving the same effect as the semiconductor device A1.

The insulating element 13 of the semiconductor device A5 includes the first insulating element 13A and the second insulating element 13B that are spaced apart from each other. The first insulating element 13A has the first transmitter/receiver 133 and the second transmitter/receiver 134. The second insulating element 13B has the third transmitter/receiver 138 and the fourth transmitter/receiver 139. The third transmitter/receiver 138 is electrically connected to the second transmitter/receiver 134. In the thickness direction z, the second transmitter/receiver 134 and the third transmitter/receiver 138 are located closer to the dummy element 14 than are the first transmitter/receiver 133 and the fourth transmitter/receiver 139. Such a configuration allows the potential difference between the first transmitter/receiver 133 and the second transmitter/receiver 134 to be set small in the first insulating element 13A. Also, the potential difference between the third transmitter/receiver 138 and the fourth transmitter/receiver 139 can be set small in the second insulating element 13B. That is, the potential difference generated in each of the first insulating element 13A and the second insulating element 13B is reduced. Moreover, the potential difference between the die pad 21 and the insulating element 13 is also reduced. This leads to more effective improvement of the dielectric strength between the die pad 21 and the insulating element 13. Unlike the semiconductor device A1, the semiconductor device A5 does not need to provide the relay unit 135 in the insulating element 13.

### Sixth Embodiment

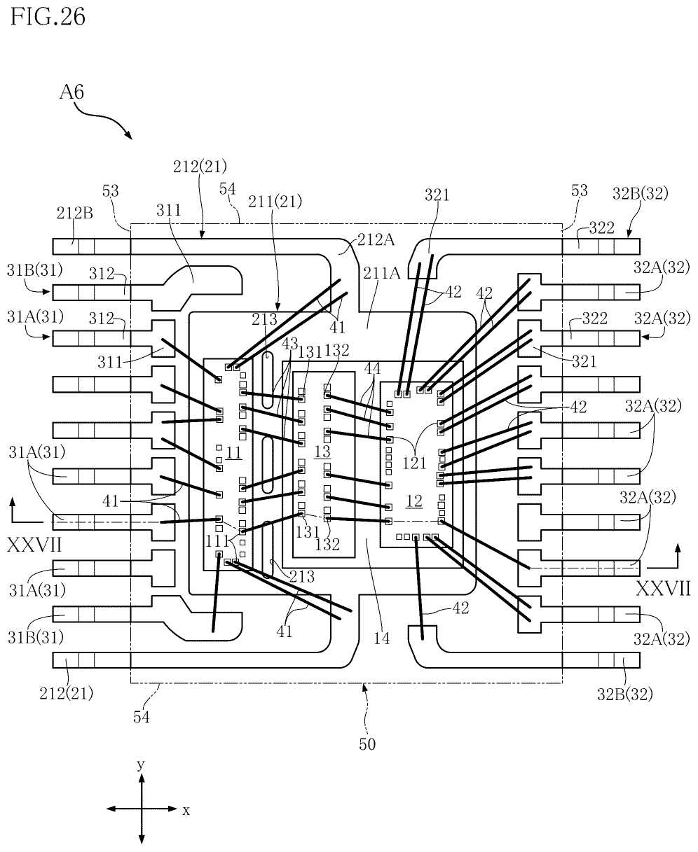

A semiconductor device A6 according to a sixth embodiment of the present disclosure will be described based in FIGS. 26 to 28. In these figures, the elements that are identical or similar to those of the above-described semiconductor device A1 are denoted by the same reference signs, and the descriptions thereof are omitted. FIG. 26 illustrates the sealing resin 50 only in its outlines for convenience of understanding. In FIG. 26, the outlines of the sealing resin 50 are shown by imaginary lines.

The semiconductor device A6 differs from the semiconductor device A1 in configurations of the second semiconductor element 12 and the die pad 21.

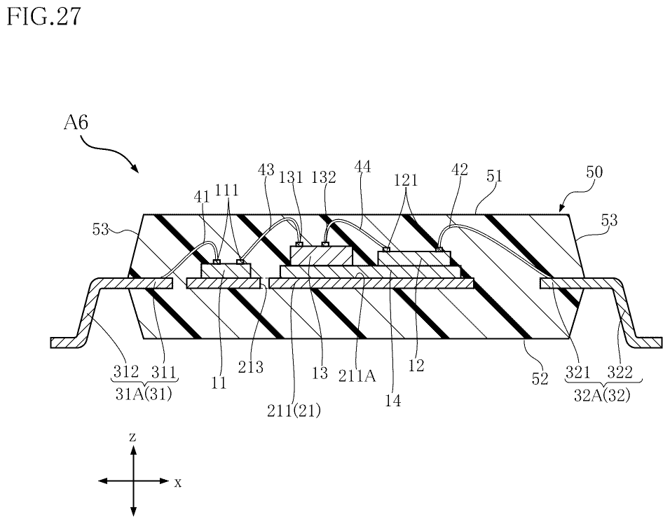

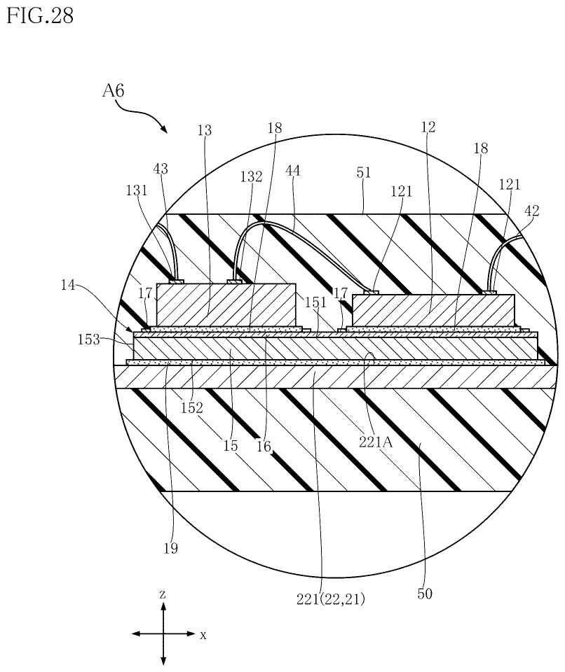

As shown in FIGS. 26 and 27, the die pad 21 is a single member, which does not include the first die pad 22 and the second die pad 23. The die pad 21 includes a pad portion 211 and two suspension lead portions 212. The first semiconductor element 11 and the second semiconductor element 12 are located on the pad portion 211. The pad portion 211 has a mounting surface 211A facing in the thickness direction z. The first semiconductor element 11 is bonded to the mounting surface 211A via a conductive bonding material (solder, metal paste, etc.), not shown. As shown in FIG. 28, the dummy element 14 is bonded to the mounting surface 211A via a second bonding layer 19. The pad portion 211 is covered with the sealing resin 50. The thickness of the pad portion 211 is 150 μm or more and 200 μm or less, for example.

As shown in FIGS. 26 and 27, the pad portion 211 is formed with a plurality of through-holes 213. Each of the through-holes 213 penetrates the pad portion 211 in the thickness direction z and extends in the second direction y. As viewed in the thickness direction z, at least one of the through-holes 213 is located between the first semiconductor element 11 and the dummy element 14. The through-holes 213 are arranged along the second direction y.

As shown in FIG. 26, the two suspension lead portions 212 are connected to opposite sides in the second direction y of the pad portion 211. The two suspension lead portions 212 each have a covered portion 212A and an exposed portion 212B. The covered portion 212A is connected to the pad portion 211 and covered with the sealing resin 50. The covered portion 212A includes a section extending in the first direction x. The exposed portion 212B is connected to the covered portion 212A and exposed from first side surface 53 of the pair of first side surfaces 53 of the sealing resin 50 where the exposed portions 312 of the first terminals 31 are exposed. The exposed portion 212B extends in the first direction x as viewed in the thickness direction z. The exposed portion 212B is bent into a gull-wing shape as viewed in the second direction y. The surface of the exposed portion 212B may be plated with tin, for example.

As shown in FIG. 26, at least one of the first wires 41 is bonded to one of the first electrodes 111 of the first semiconductor element 11 and one of the covered portions 212A of the two suspension lead portions 212. With such a configuration, at least one of the two suspension lead portions 212 forms a ground terminal electrically connected to the first semiconductor element 11.

As shown in FIGS. 26 to 28, the second semiconductor element 12 is bonded to the dummy element 14 via the first bonding layer 18. Thus, in the semiconductor device A6, the dummy element 14 is interposed between the die pad 21 and the second semiconductor element 12 or the insulating element 13, and the second semiconductor element 12 and the insulating element 13 are bonded to the dummy element 14. The area of the dummy element 14 is larger than the area of the dummy element 14 of the semiconductor device A1 as viewed in the thickness direction z. As viewed in the thickness direction z, the fourth wires 44 are located inward from the periphery 241 of the dummy element 14.

As shown in FIG. 26, at least one of the second wires 42 is bonded to one of the second electrodes 121 of the second semiconductor element 12 and one of the covered portions 321 of the two second-side terminals 32B (the second terminals 32). With such a configuration, at least one of the two second-side terminals 32B forms a ground terminal electrically connected to the second semiconductor element 12.

Next, the effects of the semiconductor device A6 will be described.

The semiconductor device A6 includes the die pad 21, the first semiconductor element 11 and the second semiconductor element 12 each mounted on the die pad 21, and the insulating element 13 that insulates the first semiconductor element 11 and the second semiconductor element 12 from each other. The semiconductor device A6 further includes the dummy element 14 bonded to the die pad 21, and the first bonding layer 18 that bonds the dummy element 14 and the insulating element 13. The dummy element 14 includes the insulating layer 16 located between the die pad 21 and the first bonding layer 18 in the thickness direction z. Thus, the semiconductor device A6 is also capable of improving the dielectric strength between the die pad 21, on which the semiconductor elements (the first semiconductor element 11 and the second semiconductor element 12) are mounted, and the insulating element 13. The semiconductor device A6 has a configuration in common with the semiconductor device A1, thereby achieving the same effect as the semiconductor device A1.

In the semiconductor device A6, the first semiconductor element 11 is bonded to the pad portion 211 of the die pad 21, and the second semiconductor element 12 is bonded to the dummy element 14. Such a configuration allows the first semiconductor element 11 and the second semiconductor element 12 to be insulated from each other by the insulating element 13 and the dummy element 14. Moreover, since the die pad 21 is a single member, the shape of the die pad 21 can be simplified.

The present disclosure is not limited to the foregoing embodiments. The specific configuration of each part of the present disclosure can be varied in design in many ways.

The present disclosure includes the embodiments described in the following clauses.

### Clause 1

A semiconductor device comprising:
a die pad;
a first semiconductor element and a second semiconductor element each mounted on the die pad;
an insulating element electrically connected to the first semiconductor element and the second semiconductor element and insulating the first semiconductor element and the second semiconductor element from each other;
a dummy element bonded to the die pad; and
a first bonding layer bonding the dummy element and the insulating element,
wherein the dummy element includes an insulating layer located between the die pad and the first bonding layer in a thickness direction.

### Clause 2

The semiconductor device according to clause 1, wherein the dummy element includes a semiconductor substrate, and
the insulating layer is layered on the semiconductor substrate.

### Clause 3

The semiconductor device according to clause 2, further comprising a second bonding layer bonding the die pad and the dummy element.

### Clause 4

The semiconductor device according to clause 3, wherein the first bonding layer and the second bonding layer are conductors.

### Clause 5

The semiconductor device according to clause 3 or 4, wherein the insulating layer is located between the semiconductor substrate and the first bonding layer.

### Clause 6

The semiconductor device according to clause 5, wherein the dummy element is formed with a protrusion protruding from the insulating layer in the thickness direction, and
the protrusion is located outside the first bonding layer as viewed in the thickness direction.

### Clause 7

The semiconductor device according to clause 6, wherein the protrusion surrounds the first bonding layer.

### Clause 8

The semiconductor device according to clause 3 or 4, wherein the insulating layer is located between the second bonding layer the semiconductor substrate.

### Clause 9

The semiconductor device according to clause 3 or 4, wherein the insulating layer includes a first layer and a second layer spaced apart from the first layer,
the first layer is located between the semiconductor substrate and the first bonding layer, and
the second layer is located between the second bonding layer and the semiconductor substrate.

### Clause 10

The semiconductor device according to any one of clauses 5 to 9, wherein the semiconductor substrate includes a first surface facing in the thickness direction and opposed to the first bonding layer, a second surface facing away from the first surface in the thickness direction, and a third surface facing in a direction orthogonal to the thickness direction, and
the semiconductor substrate is formed with a first recess recessed from the second surface and the third surface.

### Clause 11

The semiconductor device according to clause 10, wherein the first recess surrounds the second surface.

### Clause 12

The semiconductor device according to clause 10 or 11, wherein the semiconductor substrate is formed with a second recess recessed from the first surface and the third surface, and
the second recess overlaps with the first recess as viewed in the thickness direction.

### Clause 13

The semiconductor device according to clause 12, wherein the second recess surrounds the first surface.

### Clause 14

The semiconductor device according to any one of clauses 10 to 13, wherein surface roughness of the second surface is larger than surface roughness of the third surface.

### Clause 15

The semiconductor device according to any one of clauses 10 to 14, wherein the second bonding layer is surrounded by a periphery of the dummy element as viewed in the thickness direction.

### Clause 16

The semiconductor device according to any one of clauses 1 to 15, wherein the die pad includes a first die pad on which the first semiconductor element is mounted and a second die pad which is spaced apart from the first die pad and on which the second semiconductor element is mounted, and
the dummy element is bonded to the first die pad.

### Clause 17

The semiconductor device according to clause 16, wherein a voltage applied to the second semiconductor element is higher than a voltage applied to the first semiconductor element.

### Clause 18

The semiconductor device according to clause 16 or 17, further comprising:
a plurality of first terminals electrically connected to the first semiconductor element and a plurality of second terminals electrically connected to the second semiconductor element, wherein
the plurality of first terminals are located opposite to the second semiconductor element with respect to the insulating element, and
the plurality of second terminals are located opposite to the first semiconductor element with respect to the insulating element.

### REFERENCE NUMERALS

A1, A2, A3, A4, A5, A6: Semiconductor device
11: First semiconductor element
111: First electrode
12: Second semiconductor element
121: Second electrode
13: Insulating element
13A: First insulating element
13B: Second insulating element
131: First relay electrode
132: Second relay electrode
133: First transmitter/receiver
134: Second transmitter/receiver
135: Relay unit
136: Third relay electrode
137: Fourth relay electrode
138: Third transmitter/receiver
139: Fourth transmitter/receiver
14: Dummy element
15: Semiconductor substrate
15A: First substrate
15B: Second substrate
151: First surface
152: Second surface
153: Third surface
154: First recess
155: Second recess
16: Insulating layer
16A: First layer
16B: Second layer
17: Protrusion
18: First bonding layer
19: Second bonding layer
21: Die pad
211: Pad portion
211A: Mounting surface
212: Suspension lead portion
212A: Covered portion
212B: Exposed portion
213: Through-hole
22: First die pad
221: First pad portion
221A: First mounting surface
222: First suspension lead portion
222A: Covered portion
222B: Exposed portion
223: Through-hole
23: Second die pad
231: Second pad portion
231A: Second mounting surface
232: Second suspension lead portion
232A: Covered portion
232B: Exposed portion
31: First terminal
31A: First intermediate terminal
31B: First-side terminal
311: Covered portion
312: Exposed portion
32: Second terminal
32A: Second intermediate terminal
32B: Second-side terminal
321: Covered portion
322: Exposed portion
41: First wire
42: Second wire
43: Third wire
44: Fourth wire
45: Fifth wire
50: Sealing resin
51: Top surface
52: Bottom surface
53: First side surface
531: First upper portion
532: First lower portion
533: First intermediate portion
54: Second side surface
541: Second upper portion
542: Second lower portion
543: Second intermediate portion
z: Thickness direction
x: First direction
y: Second direction

1. A semiconductor device comprising:
a die pad;
a first semiconductor element and a second semiconductor element each mounted on the die pad;
an insulating element electrically connected to the first semiconductor element and the second semiconductor element and insulating the first semiconductor element and the second semiconductor element from each other;
a dummy element bonded to the die pad; and
a first bonding layer bonding the dummy element and the insulating element,
wherein the dummy element includes an insulating layer located between the die pad and the first bonding layer in a thickness direction.

2. The semiconductor device according to claim 1, wherein the dummy element includes a semiconductor substrate, and
the insulating layer is layered on the semiconductor substrate.

3. The semiconductor device according to claim 2, further comprising a second bonding layer bonding the die pad and the dummy element.

4. The semiconductor device according to claim 3, wherein the first bonding layer and the second bonding layer are conductors.

5. The semiconductor device according to claim 3, wherein the insulating layer is located between the semiconductor substrate and the first bonding layer.

6. The semiconductor device according to claim 5, wherein the dummy element is formed with a protrusion protruding from the insulating layer in the thickness direction, and
the protrusion is located outside the first bonding layer as viewed in the thickness direction.

7. The semiconductor device according to claim 6, wherein the protrusion surrounds the first bonding layer.

8. The semiconductor device according to claim 3, wherein the insulating layer is located between the second bonding layer the semiconductor substrate.

9. The semiconductor device according to claim 3, wherein the insulating layer includes a first layer and a second layer spaced apart from the first layer,
the first layer is located between the semiconductor substrate and the first bonding layer, and
the second layer is located between the second bonding layer and the semiconductor substrate.

10. The semiconductor device according to claim 5, wherein the semiconductor substrate includes a first surface facing in the thickness direction and opposed to the first bonding layer, a second surface facing away from the first surface in the thickness direction, and a third surface facing in a direction orthogonal to the thickness direction, and
the semiconductor substrate is formed with a first recess recessed from the second surface and the third surface.

11. The semiconductor device according to claim 10, wherein the first recess surrounds the second surface.

12. The semiconductor device according to claim 10, wherein the semiconductor substrate is formed with a second recess recessed from the first surface and the third surface, and
the second recess overlaps with the first recess as viewed in the thickness direction.

13. The semiconductor device according to claim 12, wherein the second recess surrounds the first surface.

14. The semiconductor device according to claim 10, wherein surface roughness of the second surface is larger than surface roughness of the third surface.

15. The semiconductor device according to claim 10, wherein the second bonding layer is surrounded by a periphery of the dummy element as viewed in the thickness direction.

16. The semiconductor device according to claim 1, wherein the die pad includes a first die pad on which the first semiconductor element is mounted and a second die pad which is spaced apart from the first die pad and on which the second semiconductor element is mounted, and
the dummy element is bonded to the first die pad.

17. The semiconductor device according to claim 16, wherein a voltage applied to the second semiconductor element is higher than a voltage applied to the first semiconductor element.

18. The semiconductor device according to claim 16, further comprising:
a plurality of first terminals electrically connected to the first semiconductor element and a plurality of second terminals electrically connected to the second semiconductor element, wherein
the plurality of first terminals are located opposite to the second semiconductor element with respect to the insulating element, and
the plurality of second terminals are located opposite to the first semiconductor element with respect to the insulating element.
